(19) United States
(12) Patent Application Publication
(10) Pub. No.: US 2026/0123179 A1
(43) Pub. Date: Apr. 30, 2026

(54) DISPLAY DEVICE, ELECTRONIC DEVICE, OPTICAL DEVICE AND VEHICLE

(71) Applicant: Samsung Display Co., Ltd., Yongin-si (KR)

(72) Inventors: Hee Ju MOON, Yongin-si (KR); Su Kyo JUNG, Yongin-si (KR); Jae Won CHO, Yongin-si (KR); Hyun Joon KIM, Yongin-si (KR); Hee Rim SONG, Yongin-si (KR); Han Byul LIM, Yongin-si (KR)

(21) Appl. No.: 19/267,310

(22) Filed: Jul. 11, 2025

(30) Foreign Application Priority Data
Oct. 29, 2024 (KR) 10-2024-0149149

(51) Int. Cl. H10K 59/121; H10K 59/122

(52) U.S. Cl. CPC H10K 59/1213; H10K 59/122

(57) ABSTRACT

A display device with improved circuit integration of a gate driver, and an electronic device, an optical device, and a vehicle each including the display device are provided. The display device includes: a substrate; a pixel transistor on the substrate; an anode electrode on the pixel transistor and connected to the pixel transistor; a light emitting layer on the anode electrode; a pixel defining film on the light emitting layer; a cathode electrode on the light emitting layer and the pixel defining film; and a gate driver in a non-display area of the substrate and connected to the pixel transistor, wherein the gate driver includes a first transistor and a second transistor on the substrate, and a first gate electrode of the first transistor and a second gate electrode of the second transistor are directly connected to each other.

### CROSS-REFERENCE TO RELATED APPLICATION

The present application claims priority to and the benefit of Korean Patent Application No. 10-2024-0149149, filed on Oct. 29, 2024, in the Korean Intellectual Property Office, the entire disclosure of which is incorporated herein by reference.

### BACKGROUND

### 1. Field

One or more embodiments of the present disclosure relate to a display device, for example, a display device with improved circuit integration of a gate driver, an electronic device, an optical device, and a vehicle.

### 2. Description of the Related Art

An organic light emitting display device includes a display element that includes organic light emitting diodes whose luminance varies with an electric current.

The organic light emitting display device includes a plurality of pixels that provide light of different colors.

### SUMMARY

One or more aspects of embodiments of the present disclosure are directed toward a display device with improved circuit integration of a gate driver, and an electronic device, an optical device, and a vehicle each including the display device. Additional aspects and features will be set forth in part in the description which follows and, in part, will be apparent from the description, or may be learned by practice of the presented embodiments of the disclosure.

According to one or more embodiments of the present disclosure, a display device includes: a substrate; a pixel transistor on the substrate; an anode electrode on (e.g., arranged on) the pixel transistor and connected to the pixel transistor; a light emitting layer on the anode electrode; a pixel defining film on the light emitting layer; a cathode electrode on the light emitting layer and the pixel defining film; and a gate driver in (e.g., arranged in) a non-display area of the substrate and connected to the pixel transistor, wherein the gate driver includes a first transistor and a second transistor on (e.g., each arranged on) the substrate, and a first gate electrode of the first transistor and a second gate electrode of the second transistor are directly connected to each other.

According to one or more embodiments of the present disclosure, an electronic device includes a display device providing a screen, wherein the display device includes: a substrate; a pixel transistor on the substrate; an anode electrode on (e.g., arranged on) the pixel transistor and connected to the pixel transistor; a light emitting layer on the anode electrode; a pixel defining film on the light emitting layer; a cathode electrode on the light emitting layer and the pixel defining film; and a gate driver in (e.g., arranged in) a non-display area of the substrate and connected to the pixel transistor, wherein the gate driver includes a first transistor and a second transistor on (e.g., each arranged on) the substrate, and a first gate electrode of the first transistor and a second gate electrode of the second transistor are directly connected to each other.

According to one or more embodiments of the present disclosure, an optical device includes: a display device; and an optical path conversion member on the display device, wherein the display device includes: a substrate; a pixel transistor on the substrate; an anode electrode on (e.g., arranged on) the pixel transistor and connected to the pixel transistor; a light emitting layer on the anode electrode; a pixel defining film on the light emitting layer; a cathode electrode on the light emitting layer and the pixel defining film; and a gate driver in (e.g., arranged in) a non-display area of the substrate and connected to the pixel transistor, wherein the gate driver includes a first transistor and a second transistor on (e.g., each arranged on) the substrate, and a first gate electrode of the first transistor and a second gate electrode of the second transistor are directly connected to each other.

According to one or more embodiments of the present disclosure, there is provided a vehicle including a display device, wherein the display device includes: a substrate; a pixel transistor on the substrate; an anode electrode on (e.g., arranged on) the pixel transistor and connected to the pixel transistor; a light emitting layer on the anode electrode; a pixel defining film on the light emitting layer; a cathode electrode on the light emitting layer and the pixel defining film; and a gate driver in (e.g., arranged in) a non-display area of the substrate and connected to the pixel transistor, wherein the gate driver includes a first transistor and a second transistor on (e.g., each arranged on) the substrate, and a first gate electrode of the first transistor and a second gate electrode of the second transistor are directly connected to each other.

In a display device, an electronic device, an optical device, and a vehicle according to one or more embodiments, a circuit integration of a gate driver may be improved. This improvement is achieved by directly connecting the gate electrode of an N-type (kind) transistor and the gate electrode of a P-type (kind) transistor in the gate driving circuit.

For example, the gate electrode of an N-type (kind) transistor and the gate electrode of a P-type (kind) transistor may be directly connected to each other in the gate driving circuit, and accordingly, the gate electrode of the N-type (kind) transistor and the gate electrode of the P-type (kind) transistor may be directly connected to each other through a contact hole without a separate interlayer connection electrode (or an intermediate electrode). This direct connection reduces the number of contact holes required for connecting the gate electrodes of the N-type and P-type transistors. Additionally, the N-type transistor and the P-type transistor may be arranged closer to each other, further enhancing circuit integration. For example, the number of the contact holes for connecting the gate electrodes of the N-type (kind) transistor and the P-type (kind) transistor may be reduced, and also, the N-type (kind) transistor and the P-type (kind) transistor may be arranged to be close to each other.

As a result, a circuit integration of a gate driver may be improved, and the size of the gate driver may be reduced. Therefore, the area occupied by the gate driver in the non-display area may be reduced, and as a result, the size of a bezel of the display device may be reduced. This allows for an increase in the display area relative to the non-display area, thereby enhancing the sense of immersion in the screen and improving the overall aesthetics of the product. Furthermore, the improved circuit integration can contribute to better performance and reliability of the display device, making it more suitable for various applications in electronic devices, optical devices, and vehicles. For example, the area of the display area may increase compared to the area of the non-display area in the display device, thereby improving a sense of immersion in a screen and product aesthetics.

The effects and aspects of the present disclosure are not limited to the above-description, and other effects and aspects which are not described herein will become apparent to those skilled in the art from the following description.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and/or other aspects will become apparent and more readily appreciated from the following description of one or more embodiments, taken in conjunction with the accompanying drawings, in which:

FIG. 1 is a perspective view of a display device according to one or more embodiments of the present disclosure;

FIG. 2 is a cross-sectional view of a display device according to one or more embodiments of the present disclosure;

FIG. 3 is a plan view of a display unit of a display device according to one or more embodiments of the present disclosure;

FIG. 4 is a block diagram of a display panel and a display driver according to one or more embodiments of the present disclosure;

FIG. 5 is a circuit diagram of a pixel of a display device according to one or more embodiments of the present disclosure;

FIG. 6 is a cross-sectional view of a display device according to one or more embodiments of the present disclosure;

FIG. 7 is a circuit diagram of a gate driver according to one or more embodiments of the present disclosure;

FIG. 8 is a diagram of array of transistors of a gate driver according to one or more embodiments of the present disclosure;

FIG. 9 is a cross-sectional view taken along the line I-I′ of FIG. 8 according to one or more embodiments of the present disclosure;

FIG. 10 is a diagram of array of a transistor and a capacitor of a gate driver according to one or more embodiments of the present disclosure;

FIG. 11 is a cross-sectional view taken along the line II-II′ of FIG. 10 according to one or more embodiments of the present disclosure;

FIG. 12 is a perspective view showing an electronic device in which a display device according to one or more embodiments is applied;

FIG. 13 is a perspective view of a head mounted display device according to one or more embodiments of the present disclosure;

FIG. 14 is an exploded perspective view illustrating an example of the head mounted display of FIG. 13 according to one or more embodiments of the present disclosure;

FIG. 15 is an illustrative view illustrating an instrument board and a center fascia of a vehicle including display devices according to one or more embodiments of the present disclosure;

FIG. 16 is a block diagram of an electronic device according to one or more embodiments of the present disclosure; and

FIGS. 17 and 18 are schematic diagrams of electronic devices according to various suitable embodiments of the present disclosure.

### DETAILED DESCRIPTION

The present disclosure will now be described more fully hereinafter with reference to the accompanying drawings, in which one or more embodiments of present disclosure are shown. This disclosure may, however, be embodied in different forms and should not be construed as limited to one or more embodiments set forth herein. Rather, these embodiments are provided so that this disclosure will be thorough and complete, and will fully convey the scope of present disclosure to those skilled in the art.

It will also be understood that if (e.g., when) a layer is referred to as being “on” another layer or substrate, it may be directly on the other layer or substrate, or one or more intervening layers may also be present therebetween. In contrast, “directly on” may refer to that there are no additional intervening elements or layers between the element or layer and the another element or layer. The same or like reference numbers indicate the same or like components throughout the disclosure. In the accompanying drawings, the thicknesses of layers and regions may be exaggerated for clarity.

Although the terms “first”, “second”, and/or the like may be used herein to describe one or more suitable elements, these elements, should not be limited by these terms. These terms may be used to distinguish one element from another element. Thus, a first element discussed may be termed a second element without departing from teachings of one or more embodiments. The description of an element as a “first” element may not require or imply the presence of a second element or other elements. The terms “first”, “second”, and/or the like may also be used herein to differentiate different categories or sets of elements. For conciseness, the terms “first”, “second”, and/or the like may represent “first-category (or first-set)”, “second-category (or second-set)”, and/or the like, respectively.

Features of various embodiments of the present disclosure may be combined partially or totally. As will be clearly appreciated by those skilled in the art, technically one or more suitable interactions and operations are possible. Various embodiments may be practiced individually or in combination.

Hereinafter, example embodiments of the disclosure will be described with reference to the accompanying drawings.

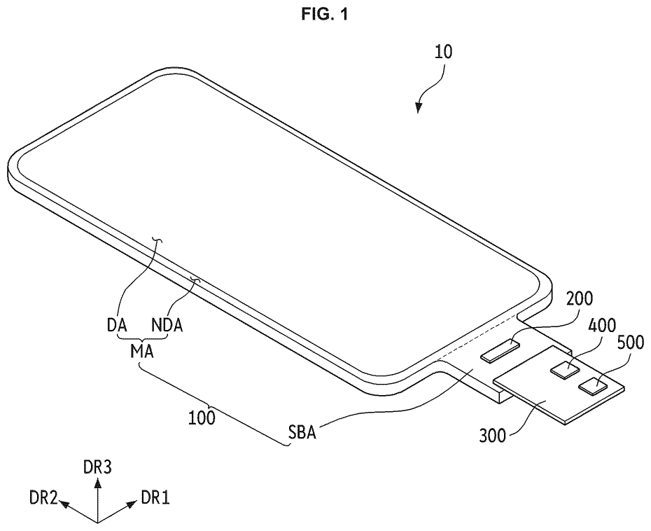

FIG. 1 is a perspective view of a display device 10 according to one or more embodiments of the present disclosure.

Referring to FIG. 1, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (loT) device. For another example, the display device 10 may be applied to wearable devices such as smart watches, watch phones, glasses-type (kind) displays, and head mounted displays.

The display device 10 according to one or more embodiments may have a planar shape similar to a quadrangle. For example, the display device 10 may have a planar shape similar to a quadrangle having short sides in a first direction DR1 and long sides in a second direction DR2. Each corner where a short side extending in the first direction DR1 meets a long side extending in the second direction DR2 may be rounded to have a set or predetermined curvature or may be right-angled. The planar shape of the display device 10 is not limited to the quadrangular shape, for example, may be similar to other polygonal shapes, a circular shape, or an oval shape.

The display device 10 may include a display panel 100, a display driver 200, a circuit board 300, a touch driver 400, and a power supply unit 500.

The display panel 100 may include a main area MA and a sub-area SBA.

The main area MA may include a display area DA including pixels that display an image and a non-display area NDA arranged around the display area DA. The display area DA may be to emit light from a plurality of emission areas or a plurality of opening areas. In one or more embodiments, the display panel 100 may include a pixel circuit including switching elements, a pixel defining film defining an emission area or an opening area, and a self-light emitting element.

In one or more embodiments, the self-light emitting element may include, but is not limited to, at least one of an organic light emitting diode including an organic light emitting layer, a quantum dot light emitting diode including a quantum dot light emitting layer, an inorganic light emitting diode including an inorganic semiconductor, or a micro light emitting diode.

The non-display area NDA may be an area outside (e.g., adjacent) the display area DA. The non-display area NDA may be defined as an edge area of the main area MA of the display panel 100. The non-display area NDA may include a gate driver which supplies gate signals to gate lines and fan-out lines which connect the display driver 200 and the display area DA.

The sub-area SBA may extend from a side of the main area MA. The sub-area SBA may include a flexible material that may be bent, folded, rolled, and/or the like. For example, if (e.g., when) the sub-area SBA is bent, it may be overlapped by the main area MA in a thickness direction (e.g., a third direction DR3). The sub-area SBA may include the display driver 200 and a pad unit connected to the circuit board 300. In one or more embodiments, the sub-area SBA may not be provided, and the display driver 200 and the pad unit may be arranged in the non-display area NDA.

The display driver 200 may output signals and voltages for driving the display panel 100. The display driver 200 may supply data voltages to data lines. The display driver 200 may supply a power supply voltage to a power line and supply a gate control signal to the gate driver. The display driver 200 may be formed as an integrated circuit and mounted on the display panel 100 by a chip on glass (COG) method, a chip on plastic (COP) method, or an ultrasonic bonding method. For example, in one or more embodiments, the display driver 200 may be arranged in the sub-area SBA and may be overlapped by the main area MA in the thickness direction (third direction DR3) by the bending of the sub-area SBA. In one or more embodiments, the display driver 200 may be mounted on the circuit board 300.

The circuit board 300 may be attached onto the pad unit of the display panel 100 using an anisotropic conductive film. Lead lines of the circuit board 300 may be electrically connected to the pad unit of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and sense a change in capacitance between the touch electrodes. For example, in one or more embodiments, the touch driving signal may be a pulse signal having a set or predetermined frequency. The touch driver 400 may determine whether an input has been made based on a change in capacitance between the touch electrodes and calculate coordinates of the input. The touch driver 400 may be formed as an integrated circuit.

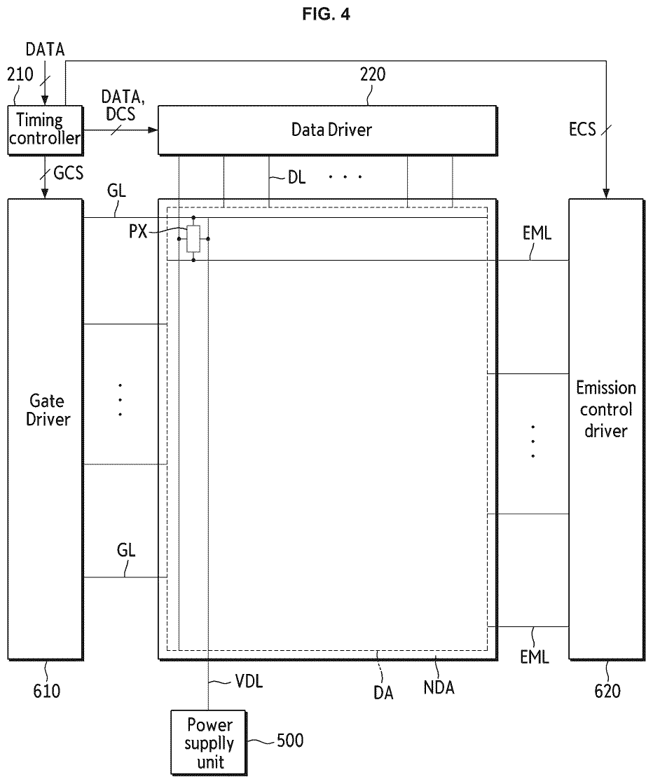

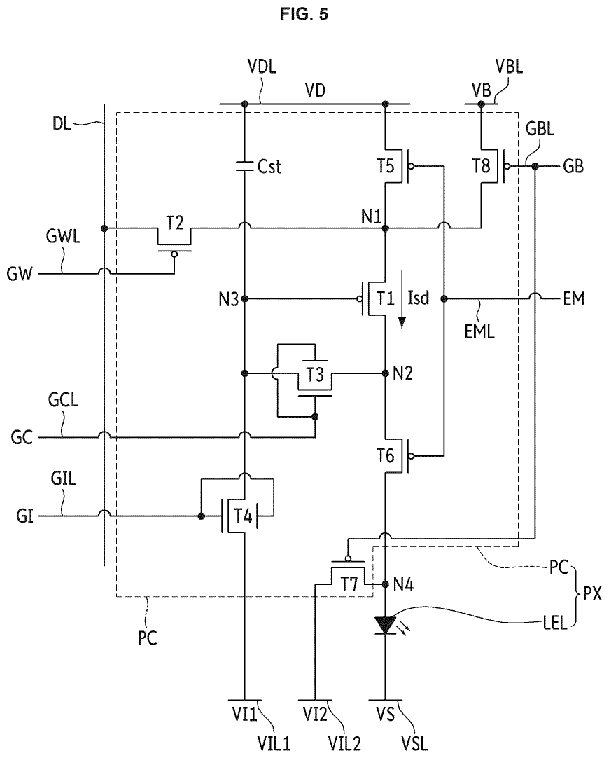

The power supply unit 500 may be arranged on the circuit board 300 and may supply a power supply voltage to the display driver 200 and the display panel 100. The power supply unit 500 may generate a driving voltage and supply the driving voltage to a driving voltage line VDL (see FIG. 4), may generate an initialization voltage (e.g., a first initialization voltage and a second initialization voltage) and supply the initialization voltage to an initialization voltage line (e.g., a first initialization voltage line VIL1 and a second initialization voltage line VIL2) (see FIG. 5), and may generate a common voltage and supply the common voltage to a common electrode common to light emitting elements of a plurality of pixels. For example, in one or more embodiments, the driving voltage may be a high potential voltage for driving the light emitting elements, and the common voltage may be a low potential voltage for driving the light emitting elements.

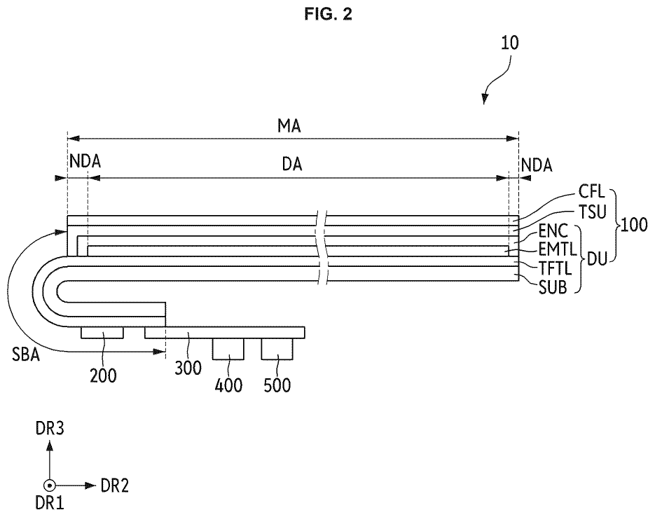

FIG. 2 is a cross-sectional view of the display device 10 according to one or more embodiments of the present disclosure.

Referring to FIG. 2, the display panel 100 may include a display unit DU, a touch sensing unit TSU, and a color filter layer CFL. The display unit DU may include a substrate SUB, a thin-film transistor layer TFTL, a light emitting element layer EMTL, and an encapsulation layer ENC.

The substrate SUB may be a base substrate or a base member. The substrate SUB may be a flexible substrate that may be bent, folded, rolled, and/or the like. For example, in one or more embodiments, the substrate SUB may include a polymer resin such as polyimide (PI), but embodiments of the present disclosure are not limited thereto. In one or more embodiments, the substrate SUB may include a glass material or a metal material.

The thin-film transistor layer TFTL may be arranged on the substrate SUB. The thin-film transistor layer TFTL may include a plurality of thin-film transistors constituting pixel circuits of pixels. The thin-film transistor layer TFTL may further include gate lines, data lines, power lines, gate control lines, fan-out lines connecting the display driver 200 and the data lines, and lead lines connecting the display driver 200 and the pad unit. Each of the thin-film transistors may include a semiconductor region, a source electrode, a drain electrode, and a gate electrode. For example, if (e.g., when) the gate driver is formed on a side of the non-display area NDA of the display panel 100, it may include thin-film transistors.

The thin-film transistor layer TFTL may be arranged in the display area DA, the non-display area NDA, and the sub-area SBA. The thin-film transistors of the pixels, the gate lines, the data lines, and the power lines of the thin-film transistor layer TFTL may be arranged in the display area DA. The gate control lines and the fan-out lines of the thin-film transistor layer TFTL may be arranged in the non-display area NDA. The lead lines of the thin-film transistor layer TFTL may be arranged in the sub-area SBA.

The light emitting element layer EMTL may be arranged on the thin-film transistor layer TFTL. The light emitting element layer EMTL may include a plurality of light emitting elements, each including a pixel electrode, a light emitting layer, and a common electrode sequentially stacked to emit light, and a pixel defining film defining the pixels. The light emitting elements of the light emitting element layer EMTL may be arranged in the display area DA.

In one or more embodiments, the light emitting layer may be an organic light emitting layer including an organic material. The light emitting layer may include a hole transporting layer, an organic light emitting layer, and an electron transporting layer. When the pixel electrode receives a set or predetermined voltage through a thin-film transistor of the thin-film transistor layer TFTL and the common electrode receives a cathode voltage, holes and electrons may move to the organic light emitting layer through the hole transporting layer and the electron transporting layer, respectively. Then, the holes and the electrons may be combined with each other in the organic light emitting layer to emit light. For example, in one or more embodiments, the pixel electrode may be an anode, and the common electrode may be a cathode, but embodiments of the present disclosure are not limited thereto.

In one or more embodiments, the light emitting elements may include a quantum dot light emitting diode including a quantum dot light emitting layer, an inorganic light emitting diode including an inorganic semiconductor, or a micro light emitting diode.

The encapsulation layer ENC may cover upper and side surfaces of the light emitting element layer EMTL and may protect the light emitting element layer EMTL. The encapsulation layer ENC may include at least one inorganic layer and at least one organic layer to encapsulate the light emitting element layer EMTL.

The touch sensing unit TSU may be arranged on the encapsulation layer ENC. The touch sensing unit TSU may include a plurality of touch electrodes for sensing a user's touch in a capacitive manner and touch lines connecting the touch electrodes and the touch driver 400. For example, the touch sensing unit TSU may sense a user's touch in a mutual capacitance manner or a self-capacitance manner.

In one or more embodiments, the touch sensing unit TSU may be arranged on a separate substrate arranged on the display unit DU. In these embodiments, the substrate supporting the touch sensing unit TSU may be a base member that encapsulates the display unit DU.

The touch electrodes of the touch sensing unit TSU may be arranged in a touch sensor area overlapping the display area DA. The touch lines of the touch sensing unit TSU may be arranged in a touch peripheral area overlapping the non-display area NDA.

The color filter layer CFL may be arranged on the touch sensing unit TSU. The color filter layer CFL may include a plurality of color filters corresponding to a plurality of emission areas, respectively. Each of the color filters may selectively transmit light of a specific wavelength and block or absorb light of other wavelengths. The color filter layer CFL may be to absorb a part of light coming from the outside of the display device 10, thereby reducing reflected light caused by the external light. Therefore, the color filter layer CFL may prevent or reduce color distortion caused by reflection of external light.

Because the color filter layer CFL is directly arranged on the touch sensing unit TSU, the display device 10 may not require a separate substrate for the color filter layer CFL. Therefore, a thickness of the display device 10 may be relatively reduced. The sub-area SBA of the display panel 100 may extend from a side of the main area MA. The sub-area SBA may include a flexible material that may be bent, folded, rolled, and/or the like. For example, if (e.g., when) the sub-area SBA is bent, it may be overlapped by the main area MA in the thickness direction (third direction DR3). The sub-area SBA may include the display driver 200 and the pad unit electrically connected to the circuit board 300.

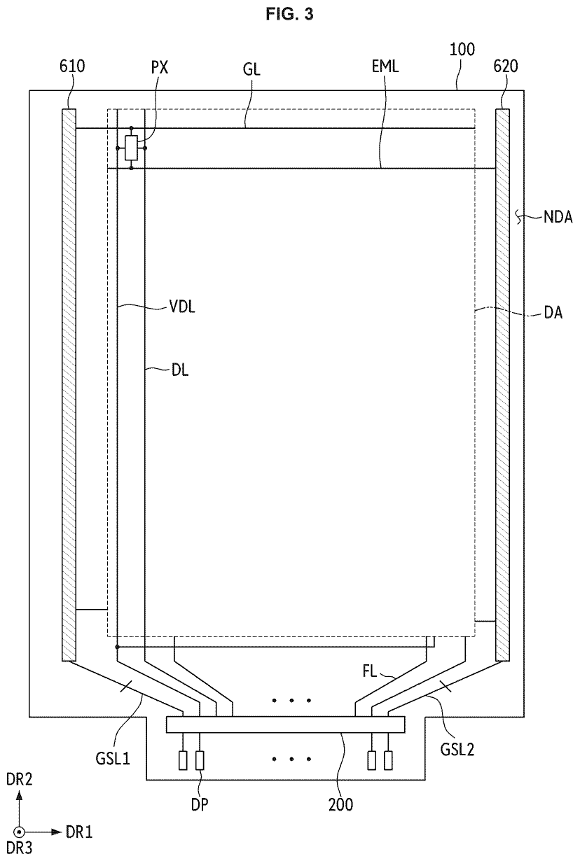

FIG. 3 is a plan view of the display unit DU of the display device 10 according to one or more embodiments of the present disclosure. FIG. 4 is a block diagram of the display panel 100 and the display driver 200 according to one or more embodiments.

Referring to FIG. 3 and FIG. 4, the display panel 100 may include the display area DA and the non-display area NDA.

The display area DA may include a plurality of pixels PX, a plurality of driving voltage lines VDL connected to the pixels PX, a plurality of gate lines GL of a plurality of common voltage lines VSL (see FIG. 5), a plurality of emission control lines EML, and a plurality of data lines DL.

Each of the pixels PX may be connected to a gate line GL, a data line DL, an emission control line EML, a driving voltage line VDL, and a common voltage line VSL. Each of the pixels PX may include at least one transistor, a light emitting element, and a capacitor.

The gate lines GL may extend in the first direction DR1 and may be spaced and/or apart (e.g., spaced apart or separated) from each other in the second direction DR2 intersecting the first direction DR1. The gate lines GL may be arranged along the second direction DR2. The gate lines GL may sequentially supply gate signals to the pixels PX.

The emission lines EML may extend in the first direction DR1 and may be spaced and/or apart (e.g., spaced apart or separated) from each other in the second direction DR2. The emission lines EML may be arranged along the second direction DR2. The emission lines EML may sequentially supply emission signals to the pixels PX.

The data lines DL may extend in the second direction DR2 and may be spaced and/or apart (e.g., spaced apart or separated) from each other in the first direction DR1. The data lines DL may be arranged along the first direction DR1. The data lines DL may supply data voltages to the pixels PX. A data voltage may determine the luminance of each of the pixels PX.

The driving voltage lines VDL may extend in the second direction DR2 and may be spaced and/or apart (e.g., spaced apart or separated) from each other in the first direction DR1. The driving voltage lines VDL may be arranged along the first direction DR1. The driving voltage lines VDL may supply a first driving voltage to the pixels PX. The first driving voltage may be a high potential voltage for driving the light emitting elements of the pixels PX.

The non-display area NDA may be around (e.g., surround) the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply data voltages received from the display driver 200 to the data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-area SBA may extend from a side of the non-display area NDA. The sub-area SBA may include the display driver 200 and a pad unit DP. The pad unit DP may be arranged closer to an edge of the sub-area SBA than the display driver 200. The pad unit DP may be electrically connected to the circuit board 300 through an anisotropic conductive film.

The display driver 200 may include a timing controller 210 and a data driver 220.

The timing controller 210 may receive digital video data DATA and timing signals from the circuit board 300. The timing controller 210 may control the operation timing of the data driver 220 by generating a data control signal DCS based on the timing signals, may control the operation timing of the gate driver 610 by generating the gate control signal GCS, and may control the operation timing of the emission control driver 620 by generating the emission control signal ECS. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. Gate signals of the gate driver 610 may select pixels PX to which the data voltages are to be supplied, and the selected pixels PX may receive the data voltages through the data lines DL.

The power supply unit 500 may be arranged on the circuit board 300 to supply a power supply voltage to the display driver 200 and the display panel 100. The power supply unit 500 may generate a driving voltage and supply the driving voltage to a driving voltage line VDL, may generate an initialization voltage and supply the initialization voltage to an initialization voltage line, and may generate a common voltage and supply the common voltage to a common electrode common to the light emitting elements of the pixels.

The gate driver 610 may be arranged outside (e.g., adjacent) one side of the display area DA or on one side of the non-display area NDA, and the emission control driver 620 may be arranged outside (e.g., adjacent) the other side of the display area DA or on the other side of the non-display area NDA. However, embodiments of the present disclosure are not limited thereto. In one or more embodiments, the gate driver 610 and the emission control driver 620 may be both arranged on either one side or the other side of the non-display area NDA.

The gate driver 610 may include a plurality of transistors that generate gate signals based on the gate control signal GCS. The emission control driver 620 may include a plurality of transistors that generate emission signals based on the emission control signal ECS. For example, in one or more embodiments, the transistors of the gate driver 610 and the transistors of the emission control driver 620 may be formed on a same layer as the transistors of each of the pixels PX. The gate driver 610 may supply the gate signals to the gate lines GL, and the emission control driver 620 may supply the emission signals to the emission control lines EML.

FIG. 5 is a circuit diagram of a pixel of the display device according to one or more embodiments of the present disclosure. For example, FIG. 5 may be a circuit diagram in respect to a pixel of FIG. 3.

A pixel PX may be arranged in the display area DA. In the display area DA, the pixel PX may be connected to a first gate line GWL, a second gate line GCL, a third gate line GIL, a fourth gate line GBL, an emission control line EML, a data line DL, a driving voltage line VDL, a common voltage line VSL, a first initialization voltage line VIL1, and a second initialization voltage line VIL2.

The pixel PX may include a pixel circuit PC and a light emitting element LEL. The pixel circuit PC may include a first transistor T1 (e.g., first pixel transistor), a second transistor T2 (e.g., second pixel transistor), a third transistor T3 (e.g., third pixel transistor), a fourth transistor T4 (e.g., fourth pixel transistor), a fifth transistor T5 (e.g., fifth pixel transistor), a sixth transistor T6 (e.g., sixth pixel transistor), a seventh transistor T7 (e.g., seventh pixel transistor), an eighth transistor T8 (e.g., eighth pixel transistor), and a capacitor Cst.

The first transistor T1 may include a gate electrode, a source electrode, and a drain electrode. The first transistor T1 may control a source-drain current (hereinafter, referred to as a driving current) according to a data voltage applied to the gate electrode. The driving current (e.g., Isd) flowing through a channel region of the first transistor T1 may be proportional to the square of a difference between a voltage Vsg between the source electrode and the gate electrode of the first transistor T1 and a threshold voltage Vth (Isd=kx (Vsg-Vth) 2), where k is a proportional coefficient determined by the structure and physical characteristics of the first transistor T1, Vsg is a source-gate voltage of the first transistor T1, and Vth is a threshold voltage of the first transistor T1.

The light emitting element LEL may receive the driving current Isd and emit light. The amount of light emitted from the light emitting element LEL or the luminance of the light emitting element LEL may be proportional to the magnitude of the driving current Isd.

In one or more embodiments, the light emitting element LEL may be an organic light emitting diode including a first electrode (e.g., an anode or a pixel electrode), a second electrode (e.g., a cathode or a common electrode), and an organic light emitting layer arranged between the first electrode and the second electrode. In one or more embodiments, the light emitting element LEL may be an inorganic light emitting element including a first electrode, a second electrode, and an inorganic semiconductor arranged between the first electrode and the second electrode. In one or more embodiments, the light emitting element LEL may be a quantum dot light emitting element including a first electrode, a second electrode, and a quantum dot light emitting layer arranged between the first electrode and the second electrode. In one or more embodiments, the light emitting element LEL may be a micro light emitting diode.

The first electrode of the light emitting element LEL may be electrically connected to a fourth node N4. The first electrode of the light emitting element LEL may be connected to a drain electrode of the sixth transistor T6 and a source electrode of the seventh transistor T7 through the fourth node N4. The second electrode of the light emitting element LEL may be connected to the common voltage line VSL. The second electrode of the light emitting element LEL may receive a second driving voltage VS (e.g., a low potential voltage) from the common voltage line VSL.

The second transistor T2 may be turned on by a first gate signal GW of the first gate line GWL to electrically connect the data line DL and a first node N1 which is the source electrode of the first transistor T1. The second transistor T2 turned on based on the first gate signal GW may supply a data voltage to the first node N1. The second transistor T2 may have a gate electrode electrically connected to the first gate line GWL, a source electrode electrically connected to the data line DL, and a drain electrode electrically connected to the first node N1.

The third transistor T3 may be turned on by a second gate signal GC of the second gate line GCL to electrically connect a second node N2 which is the drain electrode of the first transistor T1 and a third node N3 which is the gate electrode of the first transistor T1. The third transistor T3 may be connected between the third node N3 and the second node N2. For example, the third transistor T3 may have a gate electrode electrically connected to the second gate line GCL, a source electrode electrically connected to the third node N3, and a drain electrode electrically connected to the second node N2. The third transistor T3 turned on by the second gate signal GC of the second gate line GCL may electrically connect the second node N2 which is the drain electrode of the first transistor T1 and the third node N3 which is the gate electrode of the first transistor T1. The third transistor T3 may be a double gate transistor having two gate electrodes (e.g., a gate electrode and a counter gate electrode). The gate electrode and the counter gate electrode may be arranged to face each other on different layers.

The fourth transistor T4 may be turned on by a third gate signal GI of the third gate line GIL to electrically connect the third node N3 which is the gate electrode of the first transistor T1 and the first initialization voltage line VIL1. The fourth transistor T4 may be connected in series between the third node N3 and the first initialization voltage line VIL1. For example, the fourth transistor T4 may have a gate electrode electrically connected to the third gate line GIL, a source electrode electrically connected to the third node N3, and a drain electrode electrically connected to the first initialization voltage line VIL1. The fourth transistor T4 may be a double gate transistor. The first initialization voltage line VIL1 may be configured to transmit a first initialization voltage VI1.

The fifth transistor T5 may be turned on by an emission signal EM of the emission line EML to electrically connect the driving voltage line VDL and the first node N1 which is the source electrode of the first transistor T1. The fifth transistor T5 may have a gate electrode electrically connected to the emission control line EML, a source electrode electrically connected to the driving voltage line VDL, and a drain electrode electrically connected to the first node N1.

The sixth transistor T6 may be turned on by the emission signal EM of the emission line EML to electrically connect the second node N2 which is the drain electrode of the first transistor T1 and the fourth node N4 which is the first electrode of the light emitting element LEL. The sixth transistor T6 may have a gate electrode electrically connected to the emission control line EML, a source electrode electrically connected to the second node N2, and the drain electrode electrically connected to the fourth node N4. When the fifth transistor T5, the first transistor T1, and the sixth 1 transistor T6 are all turned on, the driving current Isd may be supplied to the light emitting element LEL.

The seventh transistor T7 may be turned on by a fourth gate signal GB of the fourth gate line GBL to electrically connect the fourth node N4 which is the first electrode of the light emitting element LEL and the second initialization voltage line VIL2. The seventh transistor T7 turned on based on the fourth gate signal GB may discharge the first electrode of the light emitting element LEL to a second initialization voltage VI2. The seventh transistor T7 may have a gate electrode electrically connected to the fourth gate line GBL, the source electrode electrically connected to the fourth node N4, and a drain electrode electrically connected to the second initialization voltage line VIL2. The second initialization voltage line VIL2 may be configured to transmit the second initialization voltage VI2.

The eighth transistor T8 may be turned on by the fourth gate signal GB of the fourth gate line GBL to electrically connect a bias voltage line VBL and the first node N1 which is the source electrode of the first transistor T1. The eighth transistor T8 turned on based on the fourth gate signal GB may supply a bias voltage VB to the first node N1. The eighth transistor T8 may improve the hysteresis of the first transistor T1 by supplying the bias voltage VB to the source electrode of the first transistor T1. The eighth transistor T8 may have a gate electrode electrically connected to the fourth gate line GBL, a source electrode electrically connected to the bias voltage line VBL, and a drain electrode electrically connected to the first node N1.

Each of the first transistor T1, the second transistor T2, the fifth transistor T5, the sixth transistor T6, the seventh transistor T7, and the eighth transistor T8 may include a silicon-based active layer. For example, in one or more embodiments, each of the first transistor T1, the second transistor T2, the fifth transistor T5, the sixth transistor T6, the seventh transistor T7, and the eighth transistor T8 may be a P-type (kind) transistor including an active layer made of low temperature polycrystalline silicon (LTPS). The active layer made of low temperature polycrystalline silicon may have high electron mobility and excellent or suitable turn-on characteristics. Therefore, the display device 10 including transistors with excellent or suitable turn-on characteristics may stably and efficiently drive the pixels PX. Each of the first transistor T1, the second transistor T2, the fifth transistor T5, the sixth transistor T6, the seventh transistor T7, and the eighth transistor T8 may output a current, which flows into the source electrode, to the drain electrode based on a gate-low voltage applied to the gate electrode.

Each of the third transistor T3 and the fourth transistor T4 may be an N-type (kind) transistor including an oxide-based active layer. A transistor including an oxide-based active layer may have a coplanar structure in which a gate electrode is arranged at the top. The transistor including the oxide-based active layer may output a current, which flows into a drain electrode, to a source electrode based on a gate-high voltage applied to the gate electrode.

The capacitor Cst may be electrically connected between the third node N3 which is the gate electrode of the first transistor T1 and the driving voltage line VDL. For example, a first electrode of the capacitor Cst may be electrically connected to the third node N3, and a second electrode of the capacitor Cst may be electrically connected to the driving voltage line VDL, thereby maintaining a potential difference between the driving voltage line VDL and the gate electrode of the first transistor T1.

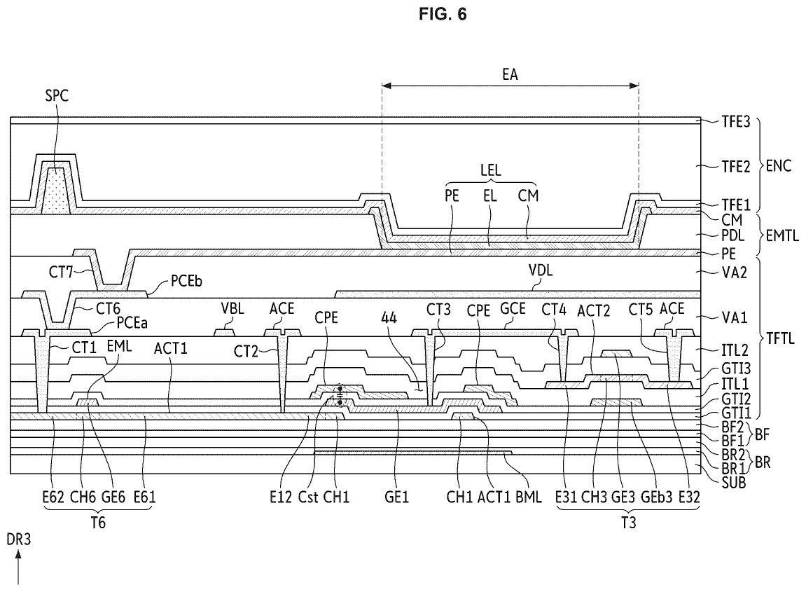

FIG. 6 is a cross-sectional view of a display device according to one or more embodiments of the present disclosure. For example, FIG. 6 may be a cross-sectional view of the display device including a pixel of FIG. 5 according to one or more embodiments.

As illustrated in FIG. 6, the display device 10 may include a substrate SUB, a barrier layer BR, a thin-film transistor layer TFTL, a light emitting element layer EMTL, and an encapsulation layer ENC. The barrier layer BR, the thin-film transistor layer TFTL, the light emitting element layer EMTL, and the encapsulation layer ENC may be sequentially arranged on the substrate SUB along the third direction DR3.

The substrate SUB may be a rigid substrate or a flexible substrate that may be bent, folded, or rolled. In one or more embodiments, the substrate SUB may be made of an insulating material such as glass, quartz, or a polymer material (e.g., polymer resin). The polymer material may be, for example, polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), and/or a (e.g., any suitable) combination thereof. In one or more embodiments, the substrate SUB may include a metal material.

As illustrated in FIG. 6, the barrier layer BR may be arranged on the substrate SUB. The barrier layer BR may be arranged on an entire surface of the substrate SUB. The barrier layer BR may be a layer for protecting transistors T1 through T8 of the thin-film transistor layer TFTL and a light emitting layer EL of the light emitting element layer EMTL from moisture introduced through the substrate SUB which is vulnerable to moisture penetration.

The barrier layer BR may be composed of a plurality of inorganic layers stacked alternately. For example, in one or more embodiments, the barrier layer BR may be a multilayer (e.g., including first and second barrier layers BR1 and BR2) in which one or more inorganic layers selected from among a silicon nitride layer, a silicon oxynitride layer, a silicon oxide layer, a titanium oxide layer, and an aluminum oxide layer are alternately stacked.

As illustrated in FIG. 6, a first pattern layer may be arranged on the substrate SUB. For example, a light blocking layer BML may be arranged as the first pattern layer on the substrate SUB. The light blocking layer BML may be arranged on the substrate SUB to cover the overlap region (e.g., the first channel region CH1) between a first gate electrode GE1 and a first active layer ACT1. For example, the light blocking layer BML may be arranged on the barrier layer BR to overlap the channel region CH1 of the first transistor T1 which is a driving transistor.

The light blocking layer BML may be made of, for example, a metal material such as chromium (Cr) or molybdenum (Mo) or may be made of a black ink or a black dye. If (e.g., when) the light blocking layer BML is made of a metal material, it may receive constant power. Accordingly, the light blocking layer BML may not float electrically, and the electrical characteristics of a transistor (e.g., the first transistor T1) on the light blocking layer BML may be stabilized.

As illustrated in FIG. 6, a buffer layer BF may be arranged on the light blocking layer BML. The buffer layer BF may be arranged on the entire surface of the substrate SUB including the barrier layer BR. The buffer layer BF may be a layer for protecting the transistors T1 through T8 of the thin-film transistor layer TFTL and the light emitting layer EL of the light emitting element layer EMTL from moisture introduced through the substrate SUB which is vulnerable to moisture penetration.

The buffer layer BF may be composed of a plurality of inorganic layers stacked alternately. For example, in one or more embodiments, the buffer layer BF may be a multilayer (e.g., including first and second buffer layers BF1 and BF2) in which one or more inorganic layers selected from among a silicon nitride layer, a silicon oxynitride layer, a silicon oxide layer, a titanium oxide layer, and an aluminum oxide layer are alternately stacked.

A second pattern layer may be arranged on the buffer layer BF. For example, the first active layer ACT1 may be arranged as the second pattern layer on the buffer layer BF. The first active layer ACT1 may include the first channel region CH1 of the first transistor T1, a second electrode E12 of the first transistor T1, the first channel region CH1 of the first transistor T1, a first electrode E61 of the sixth transistor T6, a second electrode E62 of the sixth transistor T6, and a sixth channel region CH6 of the sixth transistor T6.

The first active layer ACT1 may be an active layer made of low temperature polycrystalline silicon (LTPS).

A first gate insulating layer GTI1 may be arranged on the second pattern layer. For example, the first gate insulating layer GTI1 may be arranged on the first active layer ACT1. Here, the first gate insulating layer GTI1 may be arranged on the entire surface of the substrate SUB including the first active layer ACT1.

The first gate insulating layer GTI1 may include at least one of tetraethylorthosilicate (TEOS), silicon nitride (SiNx), or silicon oxide (SiO₂). For example, in one or more embodiments, the first gate insulating layer GTI1 may have a double-layer structure in which a silicon nitride layer with a thickness of about 40 nanometers (nm) and a tetraethylorthosilicate layer with a thickness of about 80 nm are sequentially stacked.

A third pattern layer may be arranged on the first gate insulating layer GTI1. For example, a first gate electrode GE1, a sixth gate electrode GE6, and an emission control line EML may be arranged as the third pattern layer on the first gate insulating layer GTI1. The first gate electrode GE1 may be arranged on the first gate insulating layer GTI1 to overlap the first channel region CH1 of the first active layer ACT1. The sixth gate electrode GE6 of the emission control line EML may be arranged on the first gate insulating layer GTI1 to overlap the sixth channel region CH6 of the first active layer ACT1.

The third pattern layer may include at least one of molybdenum (Mo), copper (Cu), aluminum, or titanium (Ti) and may be a single layer or a multilayer. For example, in one or more embodiments, the first gate electrode GE1 may be a triple layer including a titanium layer, an aluminum layer, and a titanium layer sequentially arranged on the first gate insulating layer GTI1 along the third direction DR3.

A second gate insulating layer GTI2 may be arranged on the third pattern layer. For example, the second gate insulating layer GTI2 may be arranged on the first gate electrode GE1, the sixth gate electrode GE6, and the emission control line EML. Here, the second gate insulating layer GTI2 may be arranged on the entire surface of 1 the substrate SUB including the first gate electrode GE1, the sixth gate electrode GE6, and the emission control line EML.

The second gate insulating layer GTI2 may include a same material and structure as the first gate insulating layer GTI1 described above.

A fourth pattern layer may be arranged on the second gate insulating layer GTI2. For example, a capacitor electrode CPE and a third counter gate electrode GEb3 may be arranged as the fourth pattern layer on the second gate insulating layer GTI2. The capacitor electrode CPE may be arranged on the second gate insulating layer GTI2 to overlap the first gate electrode GE1. The capacitor Cst may be formed between the capacitor electrode CPE and the first gate electrode GE1.

The fourth pattern layer may have a same material or structure as the third pattern layer described above.

A first interlayer insulating layer ITL1 may be arranged on the fourth pattern layer. For example, the first interlayer insulating layer ITL1 may be arranged on the capacitor electrode CPE and the third counter gate electrode GEb3. Here, the first interlayer insulating layer ITL1 may be arranged on the entire surface of the substrate SUB including the capacitor electrode CPE and the third counter gate electrode GEb3.

In one or more embodiments, the first interlayer insulating layer ITL1 may include an inorganic layer, for example, a silicon nitride layer, a silicon oxynitride layer, a silicon oxide layer, a titanium oxide layer, or an aluminum oxide layer. In one or more embodiments, the first interlayer insulating layer ITL1 may include a plurality of inorganic layers.

A fifth pattern layer may be arranged on the first interlayer insulating layer ITL1. For example, a second active layer ACT2 may be arranged as the fifth pattern layer on the first interlayer insulating layer ITL1. The second active layer ACT2 may include a first electrode E31 of the third transistor T3, a second electrode E32 of the third transistor T3, and a third channel region CH3 of the third transistor T3. The third channel region CH3 of the second active layer ACT2 may overlap the third counter gate electrode GEb3.

The second active layer ACT2 may be an oxide-based active layer. For example, in one or more embodiments, the second active layer ACT2 may be an oxide semiconductor including indium-gallium-zinc-oxide (IGZO) or indium-gallium-zinc-tin oxide (IGZTO).

A third gate insulating layer GTI3 may be arranged on the fifth pattern layer. For example, the third gate insulating layer GTI3 may be arranged on the second active layer ACT2. The third gate insulating layer GTI3 may be arranged on the entire surface of the substrate SUB including the second active layer ACT2.

The third gate insulating layer GTI3 may have a same material and structure as the first gate insulating layer GTI1 described above.

A sixth pattern layer may be arranged on the third gate insulating layer GTI3. For example, a third gate electrode GE3 may be arranged as the sixth pattern layer on the third gate insulating layer GTI3. The third gate electrode GE3 may be arranged to overlap the third channel region CH3 of the second active layer ACT2.

The sixth pattern layer may have a same material or structure as the third pattern layer described above.

A second interlayer insulating layer ITL2 may be arranged on the sixth pattern layer. For example, the second interlayer insulating layer ITL2 may be arranged on the third gate electrode GE3. The second interlayer insulating layer ITL2 may be arranged on the entire surface of the substrate SUB including the third gate electrode GE3.

The second interlayer insulating layer ITL2 may have a same material and structure as the first interlayer insulating layer ITL1 described above.

A seventh pattern layer may be arranged on the second interlayer insulating layer ITL2. For example, a gate connection electrode GCE, an active connection electrode ACE, a bias voltage line VBL, and a lower pixel connection electrode PCEa may be arranged as the seventh pattern layer on the second interlayer insulating layer ITL2. The lower pixel connection electrode PCEa may be connected to the second electrode E62 of the sixth transistor T6 through a first contact hole CT1 penetrating the second interlayer insulating layer ITL2, the third gate insulating layer GTI3, the first interlayer insulating layer ITL1, the second gate insulating layer GTI2, and the first gate insulating layer GTI1. The active connection electrode ACE may be connected to the second electrode E12 of the first transistor T1 and the first electrode E61 of the sixth transistor T6 through a second contact hole CT2 penetrating the second interlayer insulating layer ITL2, the third gate insulating layer GTI3, the first interlayer insulating layer ITL1, the second gate insulating layer GTI2, and the first gate insulating layer GTI1. In addition, the active connection electrode ACE may be connected to the second electrode E32 of the third transistor T3 through a fifth contact hole CT5 penetrating the second interlayer insulating layer ITL2 and the third gate insulating layer GTI3. The gate connection electrode GCE may be connected to the first gate electrode GE1 through a third contact hole CT3 penetrating the second interlayer insulating layer ITL2, the third gate insulating layer GTI3, the first interlayer insulating layer ITL1, a hole 44 of the capacitor electrode CPE, and the second gate insulating layer GTI2. In addition, the gate connection electrode GCE may be connected to the first electrode E31 of the third transistor T3 through a fourth contact hole CT4 penetrating the second interlayer insulating layer ITL2 and the third gate insulating layer GTI3. The first contact hole CT1, the second contact hole CT2, the third contact hole CT3, the fourth contact hole CT4, and the fifth contact hole CT5 may belong to a first type (kind) contact holes (CTa).

The seventh pattern layer may have a same material or structure as the third pattern layer described above.

A first planarization layer VA1 may be arranged on the seventh pattern layer. For example, the first planarization layer VA1 may be arranged on the gate connection electrode GCE, the active connection electrode ACE, the bias voltage line VBL, and the lower pixel connection electrode PCEa. The first planarization layer VA1 may be arranged on the entire surface of the substrate SUB including the gate connection electrode GCE, the active connection electrode ACE, the bias voltage line VBL, and the lower pixel connection electrode PCEa.

The first planarization layer VA1 may include an organic layer such as an acryl resin, an epoxy resin, a phenolic resin, a polyamide resin, and/or a polyimide resin.

An eighth pattern layer may be arranged on the first planarization layer VA1. For example, a driving voltage line VDL, and an upper pixel connection electrode PCEb may be arranged as the eighth pattern layer on the first planarization layer VA1.

The upper pixel connection electrode PCEb may be connected to the lower pixel connection electrode PCEa through a sixth contact hole CT6 penetrating the first planarization layer VA1.

The eighth pattern layer may have a same material or structure as the third pattern layer described above.

A second planarization layer VA2 may be arranged on the eighth pattern layer. For example, the second planarization layer VA2 may be arranged on the driving voltage line VDL and the upper pixel connection electrode PCEb. The second planarization layer VA2 may be arranged on the entire surface of the substrate SUB including the driving voltage line VDL and the upper pixel connection electrode PCEb.

The second planarization layer VA2 may have a same material and structure as the first planarization layer VA1 described above.

A ninth pattern layer may be arranged on the second planarization layer VA2. For example, the light emitting element layer EMTL including the ninth pattern layer may be arranged on the second planarization layer VA2. For example, a pixel electrode PE may be arranged as the ninth pattern layer on the second planarization layer VA2. The pixel electrode PE may be connected to the upper pixel connection electrode PCEb through a seventh contact hole CT7 penetrating the second planarization layer VA2.

The light emitting element layer EMTL may further include a light emitting element LEL and a pixel defining film PDL in addition to the ninth pattern layer described above.

The light emitting element LEL may include the pixel electrode PE, the light emitting layer EL, and a common electrode CM. An emission area EA is an area where the pixel electrode PE, the light emitting layer EL, and the common electrode CM are sequentially stacked so that holes from the pixel electrode PE and electrons from the common electrode CM are combined with each other in the light emitting layer EL to emit light. In this regard, the pixel electrode PE may be an anode of the light emitting element LEL, and the common electrode CM may be a cathode of the light emitting element LEL.

In a top emission structure in which light is emitted in a direction from the light emitting layer EL toward the common electrode CM, the pixel electrode PE may be formed as a single layer of molybdenum (Mo), titanium (Ti), copper (Cu), or aluminum (Al) or, in order to increase reflectivity, may be formed as a stacked structure (Ti/Al/Ti) of aluminum and titanium, a stacked structure (ITO/AI/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining film PDL may define emission areas EA of pixels. To this end, the pixel defining film PDL may be arranged on the second planarization layer VA2 to expose a portion of the pixel electrode PE. The pixel defining film PDL may cover edges of the pixel electrode PE. The pixel defining film PDL may be arranged in the seventh contact hole CT7 penetrating the second planarization layer VA2. Accordingly, the seventh contact hole CT7 penetrating the second planarization layer VA2 may be filled with the pixel defining film PDL. The pixel defining film PDL may be made of an organic layer such as an acryl resin, an epoxy resin, a phenolic resin, a polyamide resin, or a polyimide resin.

A spacer SPC may be arranged on the pixel defining film PDL. The spacer SPC may support a mask during a process of manufacturing the light emitting layer EL. The spacer SPC may be made of an organic layer such as an acryl resin, an epoxy resin, a phenolic resin, a polyamide resin, or a polyimide resin.

The light emitting layer EL may be formed on the pixel electrode PE. The light emitting layer EL may include an organic material to emit light of a set or predetermined color. For example, in one or more embodiments, the light emitting layer EL may include a hole transporting layer, an organic material layer, and an electron transporting layer. The organic material layer may include a host and a dopant. The organic material layer may include a material that emits set or predetermined light and may be formed using a phosphorescent material or a fluorescent material.

The light emitting element LEL described above may be provided for each pixel. For example, in one or more embodiments, a first pixel may include a first light emitting element, a second pixel may include a second light emitting element, and a third pixel may include a third light emitting element. The first light emitting element, the second light emitting element, and the third light emitting element may provide light of different colors. For example, the first light emitting element may be to emit light of a first color, the second light emitting element may be to emit light of a second color, and the third light emitting element may be to emit light of a third color.

For example, in one or more embodiments, an organic material layer of a first light emitting layer of a first emission area emitting light of the first color may be a phosphorescent material that includes a host material including carbazole biphenyl (CBP) or 1,3-bis(carbazol-9-yl) (mCP) and a dopant including any one or more selected from among bis(1-phenylisoquinoline) acetylacetonate iridium (PIQIr (acac)), bis(1-phenylquinoline) acetylacetonate iridium (PQIr (acac)), tris (1-phenylquinoline) iridium (PQIr), and octaethylporphyrin platinum (PtOEP). In one or more embodiments, the organic material layer of the first light emitting layer of the first emission area may be a fluorescent material including PBD:Eu(DBM)₃(Phen) or perylene. However, embodiments of the present disclosure are not limited thereto.

In one or more embodiments, an organic material layer of a second light emitting layer of a second emission area emitting light of the second color may be a phosphorescent material that includes a host material including CBP or mCP and a dopant material including Ir(ppy)₃(fac tris(2-phenylpyridine)iridium). In one or more embodiments, the organic material layer of the second light emitting layer of the second emission area emitting light of the second color may be a fluorescent material including tris(8-hydroxyquinolinato)aluminum (Alq₃). However, embodiments of the present disclosure are not limited thereto.

In one or more embodiments, an organic material layer of a light emitting layer of a third emission area emitting light of the third color may be a phosphorescent material that includes a host material including CBP or mCP and a dopant material including (4,6-F2ppy)₂Irpic or L2BD111. However, embodiments of the present disclosure are not limited thereto.

The common electrode CM may be arranged on the light emitting layer EL. The common electrode CM may cover the light emitting layers EL of the plurality of pixels. The common electrode CM may be a common layer commonly arranged on the plurality of light emitting layers. In one or more embodiments, a capping layer may be formed on the common electrode CM.

In the top emission structure, the common electrode CM may be made of a transparent conductive material (TCO) that can transmit light, such as indium tin oxide (ITO) or indium zinc oxide (IZO), or a semi-transmissive conductive material such as magnesium (Mg), silver (Ag), or an alloy of Mg and Ag. If (e.g., when) the common electrode CM is made of a semi-transmissive conductive material, light output efficiency may be increased by a microcavity.

The encapsulation layer ENC may be formed on the light emitting element layer EMTL. The encapsulation layer ENC may include at least one of inorganic layers TFE1 or TFE3 to prevent or reduce oxygen or moisture from penetrating into the light emitting element layer EMTL. In addition, the encapsulation layer ENC may include at least one organic layer to protect the light emitting element layer EMTL from foreign substances such as dust. For example, in one or more embodiments, the encapsulation layer ENC may include a first encapsulating inorganic layer TFE1, an encapsulating organic layer TFE2, and a second encapsulating inorganic layer TFE3.

The first encapsulating inorganic layer TFE1 may be arranged on the common electrode CM, the encapsulating organic layer TFE2 may be arranged on the first encapsulating inorganic layer TFE1, and the second encapsulating inorganic layer TFE3 may be arranged on the encapsulating organic layer TFE2. Each of the first encapsulating inorganic layer TFE1 and the second encapsulating inorganic layer TFE3 may be a multilayer in which one or more inorganic layers selected from among a silicon nitride layer, a silicon oxynitride layer, a silicon oxide layer, a titanium oxide layer, and an aluminum oxide layer are alternately stacked. The encapsulating organic layer TFE2 may be an organic layer such as an acryl resin, an epoxy resin, a phenolic resin, a polyamide resin, or a polyimide resin.

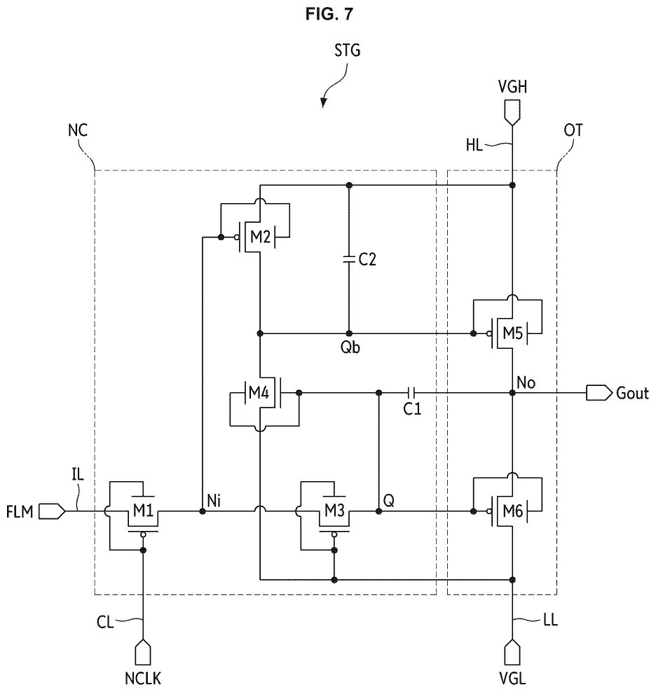

FIG. 7 is a circuit diagram of a gate driver according to one or more embodiments of the present disclosure. For example, FIG. 7 may be a circuit diagram of the gate driver 610 of FIG. 3 according to one or more embodiments.

The gate driver 610 may be arranged in the non-display area NDA. The gate driver 610 may include a plurality of stages STG arranged in the non-display area NDA. As illustrated in FIG. 7, one stage STG may include a node control unit NC and an output unit OT. The output unit OT may be connected to the node control unit NC.

The node control unit NC may include a first transistor M1, a second transistor M2, a third transistor M3, a fourth transistor M4, a first capacitor C1, and a second capacitor C2.

The output unit OT may include a fifth transistor M5 and a sixth transistor M6.

The first transistor M1 may include a first gate electrode connected to a clock line CL, a first source electrode connected to an input line IL, and a first drain electrode connected to an input node N1. The clock line CL may be to transmit a clock signal NCLK. The input line IL may be to transmit an initiation signal FLM from a timing control unit or a gate signal from a front-end stage. The initiation signal FLM applied to the input line IL may have an active level (e.g., low voltage level) or a non-active level (e.g., high level voltage). In addition, the gate signal applied to the input line IL may have an active level (e.g., low voltage level) or a non-active level (e.g., high level voltage).

The second transistor M2 may include a second gate electrode connected to the input node Ni, a second source electrode connected to a high potential power line HL, and a drain electrode connected to a reset node Qb. The high potential power line HL may be to transmit a high voltage VGH. The high voltage VGH may be a direct current voltage.

The third transistor M3 may include a third gate electrode connected to a low potential power line LL, a third source electrode connected to the input node Ni, and a third drain electrode connected to a set node Q. The low potential power line LL may be to transmit a low voltage VGL. The low voltage VGL may be a direct current voltage. The low voltage VGL may have a smaller magnitude than the above-described high voltage VGH.

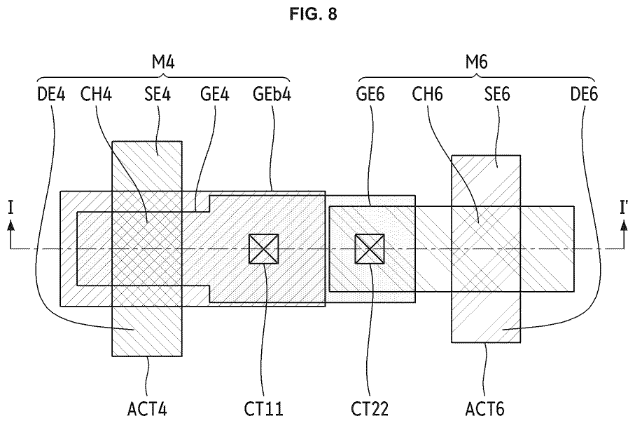

The fourth transistor M4 may include a fourth gate electrode (e.g., GE4 in FIG. 8) connected to the set node Q, a fourth source electrode (e.g., SE4 in FIG. 8) connected to the reset node Qb, and a fourth drain electrode (e.g., DE4 in FIG. 8) connected to the low potential power line LL.

The fifth transistor M5 may include a fifth gate electrode connected to the reset node Qb, a fifth source electrode connected to the high potential power line HL, and a fifth drain electrode connected to an output node No. The fifth transistor M5 may output a gate high voltage corresponding to the high voltage VGH. For example, the gate high voltage corresponding to the inactive level of a gate signal Gout may be output to the gate line (e.g., any one of GWL, GCL, GIL, and GBL) through the fifth transistor M5. The gate line may be deactivated by the gate high voltage.

The sixth transistor M6 may include a sixth gate electrode (e.g., GE6 in FIG. 8) connected to the set node Q, a sixth source electrode (e.g., SE6 in FIG. 8) connected to the output node No, and a sixth drain electrode (e.g., DE6 in FIG. 8) connected to the low potential power line LL. The sixth transistor M6 may output a gate low voltage corresponding to the low voltage VGL. For example, the gate low voltage corresponding to the active level of the gate signal Gout may be output to the gate line (e.g., any one of GWL, GCL, GIL, and GBL) through the sixth transistor M6. The gate line may be activated by the gate low voltage.

The first capacitor C1 may be connected between the set node Q and the output node No.

The second capacitor C2 may be connected between the high potential power line HL and the reset node Qb.

When each of the initiation signal FLM (or a gate signal from the front end stage) and a clock signal NCLK has a voltage of an active level, the low voltage VGL may be applied to the set node Q and the high voltage VGH may be applied to the reset node Qb so that the sixth transistor M6 is turned on while the fifth transistor M5 is turned off. Accordingly, the gate signal Gout of the gate low voltage may be outputted through the output node No. Here, the initiation signal FLM of the active level may be an initiation signal of a low level voltage, the clock signal NCLK of the active level may be a clock signal NCLK of a low level voltage, and the gate signal Gout of the active level may be a gate signal Gout of a gate low voltage.

In contrast, if (e.g., when) the initiation signal FLM (or a gate signal from the front end stage) has a voltage of a non-active level and the clock signal NCLK has a voltage of an active level, the high voltage VGH may be applied to the set node Q and the low voltage VGL may be applied to the reset node Qb so that the sixth transistor M6 is turned off and the fifth transistor M5 is turned on. Accordingly, the gate signal Gout of the gate high voltage may be outputted through the output node No. Here, the initiation signal FLM of the non-active level may be an initiation signal FLM of a high level voltage, the clock signal NCLK of the active level may be a clock signal NCLK of a low voltage level, and the gate signal Gout of the non-active level may be a gate signal Gout of a gate high voltage.

The pixel may be activated if (e.g., when) the gate signal Gout has a gate low voltage, and the pixel may be deactivated if (e.g., when) the gate signal Gout has a gate high voltage.

The gate signal Gout may be, for example, any one selected from among the first gate signal GW, the second gate signal GC, the third gate signal GI, and the fourth gate signal GB described above.

Each of the first transistor M1, the second transistor M2, the third transistor M3, the fifth transistor M5, and the sixth transistor M6 may include a silicon-based active layer. For example, in one or more embodiments, each of the first transistor M1, the second transistor M2, the third transistor M3, the fifth transistor M5, and the sixth transistor M6 may be a P-type (kind) transistor including an active layer made of low temperature polycrystalline silicon (LTPS). Each of the first transistor M1, the second transistor M2, the third transistor M3, the fifth transistor M5, and the sixth transistor M6 may output a current flowing into the source electrode to the drain electrode based on a gate low voltage applied to the gate electrode.

The fourth transistor M4 may be an N-type (kind) transistor including an oxide-based active layer. The transistor including an oxide-based active layer may have a coplanar structure with a gate electrode arranged on the top. The transistor including an oxide-based active layer may output a current flowing into the drain electrode to the source electrode based on a gate high voltage applied to the gate electrode. In one or more embodiments, the fourth transistor M4 of an N-type (kind) metal oxide semiconductor (NMOS) and the sixth transistor M6 of a P-type (kind) metal oxide semiconductor (PMOS) may be connected to each other through the gate electrodes to form a transistor structure of a complementary metal oxide semiconductor (CMOS).

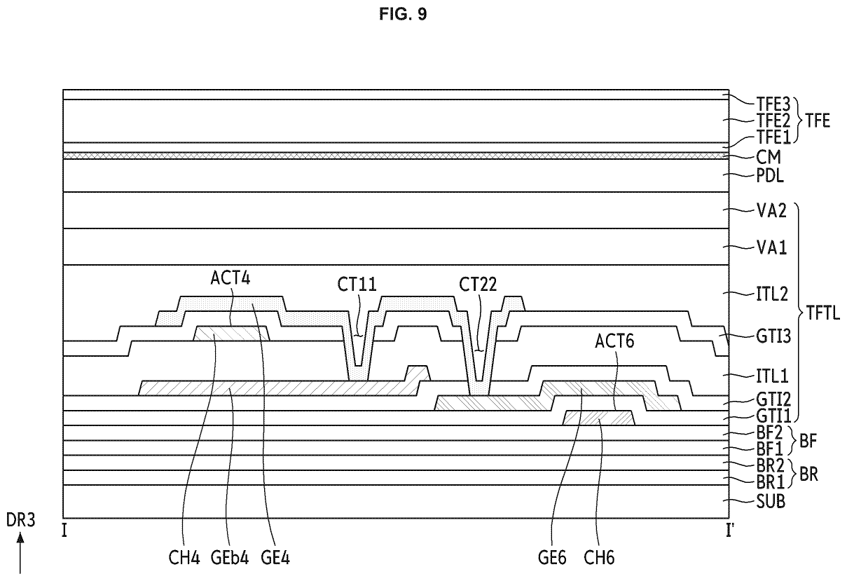

FIG. 8 is a diagram of array of transistors of the gate driver according to one or more embodiments of the present disclosure, and FIG. 9 is a cross-sectional view taken along the line I-I′ of FIG. 8 according to one or more embodiments. For example, FIG. 8 may be a diagram of array of the fourth transistor M4 and the sixth transistor M6 of FIG. 7 according to one or more embodiments, and FIG. 9 may be a cross-section view of the fourth transistor M4 and the sixth transistor M6 of FIG. 8 according to one or more embodiments.

As illustrated in FIGS. 8 and 9, the sixth transistor M6 may include a sixth channel region CH6, a sixth gate electrode GE6, a sixth source electrode SE6, and a sixth drain electrode DE6. In addition, as illustrated in FIGS. 8 and 9, the fourth transistor M4 may include a fourth channel region CH4, a fourth gate electrode GE4, a fourth counter gate electrode GEb4, a fourth source electrode SE4, and a fourth drain electrode DE4.

As illustrated in FIG. 8, the gate driver 610 of the display device 10 may include the fourth transistor M4 and the sixth transistor M6. For example, in a cross-sectional viewpoint as illustrated in FIG. 9, the display device 10 may include the fourth transistor M4 and the sixth transistor M6 arranged on a substrate SUB.

As illustrated in FIG. 9, a barrier layer BR and a buffer layer BF may be arranged on the substrate SUB. Because the barrier layer BR and the buffer layer BF of FIG. 9 are the same as the barrier layer BR and the buffer layer BF of FIG. 6 described above, respectively, the description of the barrier layer BR and the buffer layer BF of FIG. 9 may refer to FIG. 6 and related description.

A sixth active layer ACT6 may be arranged on a second buffer layer BF2. The sixth active layer ACT6 may include a sixth channel region CH6, a sixth source electrode SE6, and a sixth drain electrode DE6. The sixth active layer ACT6 may be arranged on a same layer as the first active layer ACT1 described above. The sixth active layer ACT6 may be made of a same material as the first active layer ACT1 described above. The sixth active layer ACT6 and the first active layer ACT1 may be integrally formed.

The sixth active layer ACT6 may be an active layer made of low temperature polycrystalline silicon (LTPS).

A first gate insulating layer GTI1 may be arranged on the sixth active layer ACT6.

The sixth gate electrode GE6 may be arranged on the first gate insulating layer GTI1. For example, the sixth gate electrode GE6 may be arranged on the first gate insulating layer GTI1 to overlap the sixth active layer ACT6. The sixth channel region CH6 may be arranged in a portion of the sixth active layer ACT6 overlapping the sixth gate electrode GE6. The sixth gate electrode GE6 of the sixth transistor M6 may be arranged on a same layer as the sixth gate electrode GE6 of the sixth transistor T6 illustrated in FIG. 6 described above. The sixth gate electrode GE6 of the sixth transistor M6 may be formed of a same material as the sixth gate electrode GE6 of the sixth transistor T6 illustrated in FIG. 6 described above.

A second gate insulating layer GTI2 may be arranged on the sixth gate electrode GE6.

The fourth counter gate electrode GEb4 may be arranged on the second gate insulating layer GTI2. The fourth counter gate electrode GEb4 may be arranged on a same layer as the third counter gate electrode GEb3 of FIG. 6 described above. The fourth counter gate electrode GEb4 may be formed of a same material as the third counter gate electrode GEb3 of FIG. 6 described above.

A first interlayer insulating layer ITL1 may be arranged on the fourth counter gate electrode GEb4.

A fourth active layer ACT4 may be arranged on the first interlayer insulating layer ITL1. The fourth active layer ACT4 may include the fourth channel region CH4, the fourth source electrode SE4, and the fourth drain electrode DE4 of the fourth transistor M4. The fourth active layer ACT4 may be arranged on a same layer as the second active layer ACT2 described above. The fourth active layer ACT4 may be formed of a same material as the second active layer ACT2 described above. The fourth active layer ACT4 and the second active layer ACT2 may be integrally formed.

The fourth active layer ACT4 may be an oxide-based active layer. For example, in one or more embodiments, the fourth active layer ACT4 may be an oxide semiconductor containing indium-gallium-zinc oxide (IGZO) or indium-gallium-zinc-tin oxide (IGZTO).

A third gate insulating layer GTI3 may be arranged on the fourth active layer ACT4.

The fourth gate electrode GE4 may be arranged on the third gate insulating layer GTI3. For example, the fourth gate electrode GE4 may be arranged on the third gate insulating layer GTI3 to overlap the fourth counter gate electrode GEb4, the fourth active layer ACT4, and the sixth gate electrode GE6. The fourth channel region CH4 may be arranged in a portion of the fourth active layer ACT4 overlapping the fourth gate electrode GE4 and the fourth counter gate electrode GEb4.

The fourth gate electrode GE4 may be connected to the fourth counter gate electrode GEb4 through a first contact hole CT11 penetrating the third gate insulating layer GTI3 and the first interlayer insulating layer ITL1. In addition, the fourth gate electrode GE4 may be connected to the sixth gate electrode GE6 through a second contact hole CT22 penetrating the third gate insulating layer GTI3, the first interlayer insulating layer ITL1, and the second gate insulating layer GTI2. The fourth gate electrode GE4 may be arranged on a same layer as the third gate electrode GE3 of FIG. 6 described above. The fourth gate electrode GE4 may be formed of a same material as the third gate electrode GE3 of FIG. 6 described above.

A second interlayer insulating layer ITL2, a first planarization layer VA1, a second planarization layer VA2, a pixel defining film PDL, a common electrode CM, and an encapsulation layer TFE may be sequentially arranged on the fourth gate electrode GE4 (e.g., in the stated order). Here, because the first gate insulating layer GTI1, the second gate insulating layer GTI2, the first interlayer insulating layer ITL1, the third gate insulating layer GTI3, the second interlayer insulating layer ITL2, the first planarization layer VA1, the second planarization layer VA2, the pixel defining film PDL, the common electrode CM, and the encapsulation layer TFE of FIG. 9 are the same as the first gate insulating layer GTI1, the second gate insulating layer GTI2, the first interlayer insulating layer ITL1, the third gate insulating layer GTI3, the second interlayer insulating layer ITL2, the first planarization layer VA1, the second planarization layer VA2, the pixel defining film PDL, the common electrode CM, and the encapsulation layer TFE of FIG. 6 described above, respectively, the description of the first gate insulating layer GTI1, the second gate insulating layer GTI2, the first interlayer insulating layer ITL1, the third gate insulating layer GTI3, the second interlayer insulating layer ITL2, the first planarization layer VA1, the second planarization layer VA2, the pixel defining film PDL, the common electrode CM, and the encapsulation layer TFE of FIG. 9 may refer to FIG. 6 and related description.

In one or more embodiments, a light blocking layer may be further arranged on a substrate. For example, in one or more embodiments, the light blocking layer may be further arranged between the substrate SUB and the first barrier layer BR1 to overlap the sixth active layer ACT6. The light blocking layer may overlap the sixth channel region CH6 of the sixth active layer ACT6. In this regard, the sixth gate electrode GE6 of the sixth transistor M6 may be connected to the light blocking layer through a contact hole penetrating the first gate insulating layer GTI1, the second buffer layer BF2, the first buffer layer BF1, the second barrier layer BR2, and the first barrier layer BR1. The light blocking layer of FIG. 9 may be the same as the light blocking layer BML of FIG. 6 described above. For example, the light blocking layer BML of FIG. 6 may extend further to the gate driver to overlap the sixth channel region CH6 of the sixth active layer ACT6 or cover the sixth channel region CH6.

Like described above, the sixth transistor M6 may be a double gate transistor having two gate electrodes (e.g., the sixth gate electrode GE6 and the light blocking layer BML). Similarly, each of the first transistor M1, the second transistor M2, the third transistor M3, and the fifth transistor M5 of the gate driver 610 may be formed as the double gate transistor like the sixth transistor M6 described above. To this end, the above-described light blocking layer BML may overlap each of the first channel region of the first transistor M1, the second channel region of the second transistor M2, the third channel region of the third transistor M3, and the fifth channel region of the fifth transistor M5.

According to one or more embodiments, the sixth gate electrode GE6 of the sixth transistor M6 and the fourth gate electrode GE4 of the fourth transistor M4 of opposite types (kinds) may be directly connected to (or in contact or in direct contact with) each other. For example, in one or more embodiments, the sixth gate electrode GE6 of the sixth transistor M6 of P-type (kind) and the fourth gate electrode GE4 of the fourth transistor M4 of N-type (kind) may be directly connected to (or in contact or in direct contact with) each other through the second contact hole CT22 without a separate interlayer connection electrode (or an intermediate electrode).

Accordingly, the number of contact holes for connecting the sixth gate electrode GE6 of the sixth transistor M6 and the fourth gate electrode GE4 of the fourth transistor M4 may reduce, and the sixth transistor M6 and the fourth transistor M4 may be arranged to be closer to each other. In addition, the fourth gate electrode GE4 of the fourth transistor M4 and the fourth counter gate electrode GEb4 of the fourth transistor M4 may be directly connected to (or in contact or in direct contact with) each other. For example, the fourth gate electrode GE4 of the fourth transistor M4 and the fourth counter gate electrode GEb4 of the fourth transistor M4 may be directly connected to (or in contact or in direct contact with) each other through the first contact hole CT11 without a separate interlayer connection electrode (or an intermediate electrode).

Accordingly, the magnitude or size of the fourth transistor M4 may decrease. Therefore, the circuit integration of the gate driver 610 may be improved, and the size of the gate driver 610 may decrease. As a result, the area occupied by the gate driver 610 in the non-display area NDA may be reduced, and accordingly, the size of a bezel of the display device 10 may be reduced. Consequently, the area of the display area DA may increase compared to the area of the non-display area NDA in the display device 10, thereby improving a sense of immersion in a screen and product aesthetics.

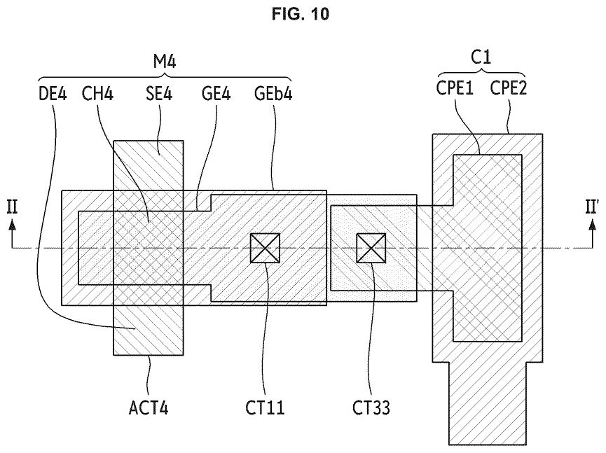

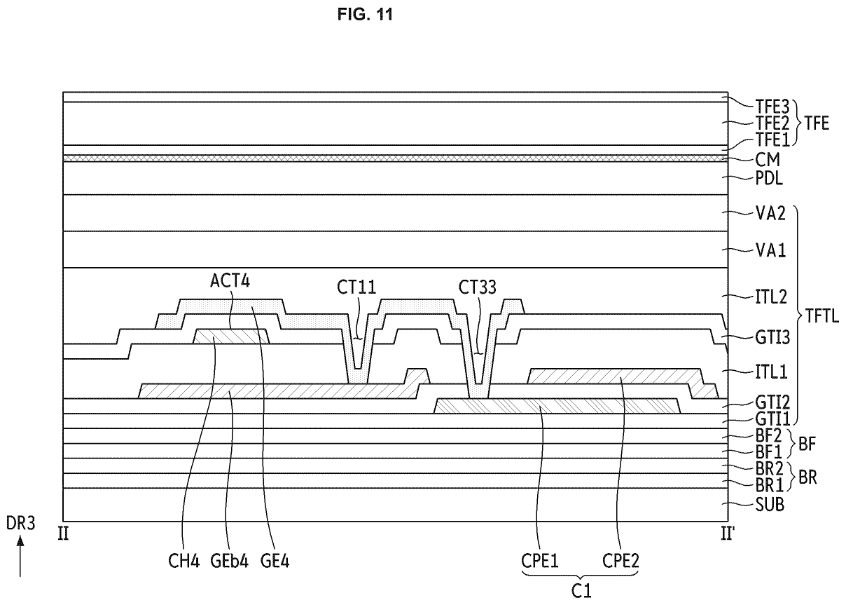

FIG. 10 is a diagram of array of a transistor and a capacitor of a gate driver according to one or more embodiments of the present disclosure, and FIG. 11 is a cross-sectional view taken along the line II-II′ of FIG. 10 according to one or more embodiments. For example, FIG. 10 may be a diagram of array of the fourth transistor M4 and the first capacitor C1 of FIG. 7 according to one or more embodiments, and FIG. 11 may be a cross-sectional view of the fourth transistor M4 and the first capacitor C1 of FIG. 10 according to one or more embodiments.

As illustrated in FIG. 10 and FIG. 11, the first capacitor C1 may include a first capacitor electrode CPE1 and a second capacitor electrode CPE2. In a cross-sectional viewpoint as illustrated in FIG. 11, the first capacitor electrode CPE1 and the second capacitor electrode CPE2 may face each other in the third direction DR3.

As illustrated in FIG. 11, a barrier layer BR and a buffer layer BF may be arranged on the substrate SUB. Because the barrier layer BR and the buffer layer BF of FIG. 11 are the same as the barrier layer BR and the buffer layer BF of FIG. 6 described above, respectively, the description of the barrier layer BR and the buffer layer BF of FIG. 11 may refer to FIG. 6 and related description.

A first gate insulating layer GTI1 may be arranged on the second buffer layer BF2.

The first capacitor electrode CPE1 may be arranged on the first gate insulating layer GTI1. The first capacitor electrode CPE1 may be arranged on a same layer as the sixth gate electrode GE6 of the sixth transistor T6 illustrated in FIG. 6 described above. In addition, the first capacitor electrode CPE1 may be arranged on a same layer as the sixth gate electrode GE6 of the sixth transistor M6 illustrated in FIG. 8 and FIG. 9 described above. The first capacitor electrode CPE1 may be formed of a same material as the sixth gate electrode GE6 of the sixth transistor T6 illustrated in FIG. 6 described above. In addition, the first capacitor electrode CPE1 may be formed of a same material as the sixth gate electrode GE6 of the sixth transistor M6 of FIG. 8 and FIG. 9 described above.

A second gate insulating layer GTI2 may be arranged on the first capacitor electrode CPE1.

The second capacitor electrode CPE2 may be arranged on the second gate insulating layer GTI2. For example, the second capacitor electrode CPE2 may be arranged on the second gate insulating layer GTI2 to overlap the first capacitor electrode CPE1. The second capacitor electrode CPE2 may be arranged on a same layer as the fourth counter gate electrode GEb4. The second capacitor electrode CPE2 may be formed of a same material as the fourth counter gate electrode GEb4.

The fourth transistor M4 may be the same as the fourth transistor M4 of FIG. 8 and FIG. 9 described above. However, as illustrated in FIG. 10 and FIG. 11, the fourth gate electrode GE4 of the fourth transistor M4 may further overlap the first capacitor electrode CPE1. For example, the fourth gate electrode GE4 may overlap the fourth active layer ACT4, the fourth counter gate electrode GE4b, the sixth gate electrode GE6, and the first capacitor electrode CPE1. In addition, the fourth gate electrode GE4 may be further connected to the first capacitor electrode CPE1 through a third contact hole CT33 penetrating a third gate insulating layer GTI3, the first interlayer insulating layer ITL1, and the second gate insulating layer GTI2. In one or more embodiments, the first capacitor electrode CPE1 and the sixth gate electrode GE6 of the sixth transistor M6 may be integrally formed.

According to one or more embodiments, the fourth gate electrode GE4 of the fourth transistor M4 and the first capacitor electrode CPE1 of the first capacitor C1 may be directly connected (or in contact or in direct contact with) each other. For example, the fourth gate electrode GE4 of the fourth transistor M4 and the first capacitor electrode CPE1 of the first capacitor C1 may be directly connected (or in contact or in direct contact with) each other through the third contact hole CT33 without a separate interlayer connection electrode (or an intermediate electrode).

Accordingly, the number of contact holes for connecting the fourth transistor and the first capacitor may reduce, and the fourth transistor M4 and the first capacitor C1 may be arranged to be closer to each other. Therefore, the circuit integration of the gate driver 610 may be improved, and the size of the gate driver 610 may decrease. Accordingly, the area occupied by the gate driver 610 in the non-display area NDA may be reduced, and accordingly, the size of a bezel of the display device 10 may be reduced. In consequence, the area of the display area DA may increase compared to the area of the non-display area NDA in the display device 10, thereby improving a sense of immersion in a screen and product aesthetics.

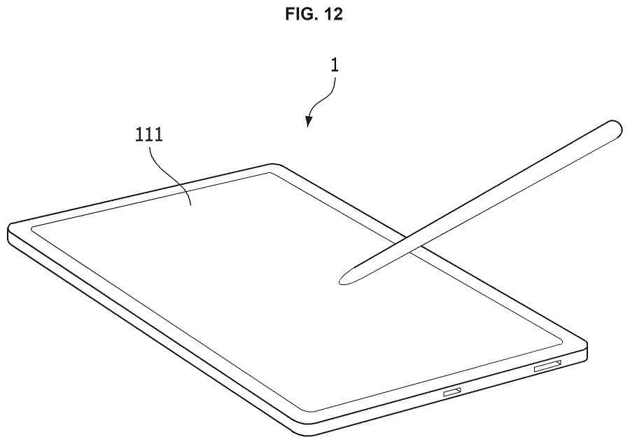

FIG. 12 is a perspective view showing an electronic device in which a display device according to one or more embodiments of the present disclosure is applied.

Referring to FIG. 12, a tablet 1 to which a display device 111 according to one or more embodiments is applied is illustrated as an example of the electronic device. However, the display device 111 according to one or more embodiments may also be applied to other electronic devices in addition to the tablet 1. For example, the display device 111 according to one or more embodiments may be applicable to an electronic device that displays a moving image or a still image. For example, the display device 111 according to one or more embodiments may be applicable to 1 portable electronic devices such as mobile phones, smart phones, smart watches, watch phones, mobile communication terminals, electronic notebooks, electronic books, PMPs, navigation devices, and UMPCs. In one or more embodiments, the display device 111 according to one or more embodiments may be used as a display screen of one or more suitable electronic devices such as a television, a notebook computer, a monitor, a billboard, and an IOT device.

The display device 111 may have a same structure as the display device 10 described throughout FIGS. 1 to 11.

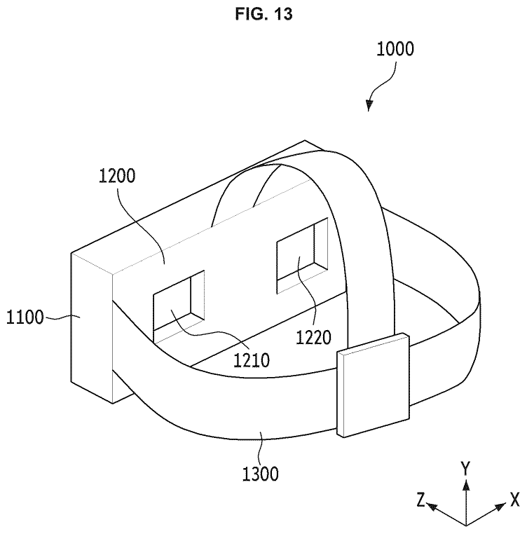

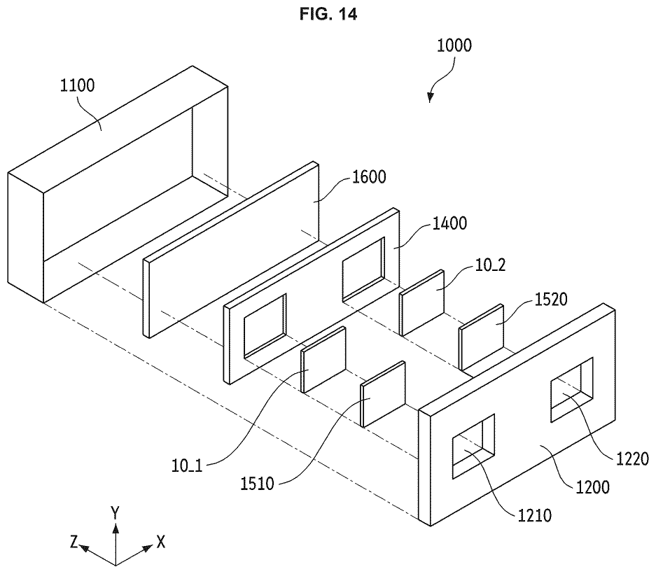

FIG. 13 is a perspective view illustrating a head mounted display according to one or more embodiments of the present disclosure. FIG. 14 is an exploded perspective view illustrating an example of the head mounted display of FIG. 13 according to one or more embodiments.

Referring to FIG. 13 and FIG. 14, a head mounted display device 1000 according to one or more embodiments includes a first display device 10_1, a second display device 10_2, a display device housing portion 1100, a housing portion cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIGS. 1 to 12, and descriptions of the first display device 10_1 and the second display device 10_2 are thus not provided for conciseness.

The first optical member 1510 may be arranged between the first display device 10_1 and the first eyepiece 1210. The second optical member 1520 may be arranged between the second display device 10_2 and the second eyepiece 1220. Each of the first optical member 1510 and the second optical member 1520 may include at least one convex lens.

The middle frame 1400 may be arranged between the first display device 10_1 and the control circuit board 1600 and arranged between the second display device 10_2 and the control circuit board 1600. The middle frame 1400 serves to support and fix the first display device 10_1, the second display device 10_2, and the control circuit board 1600.

The control circuit board 1600 may be arranged between the middle frame 1400 and the display device housing portion 1100. The control circuit board 1600 may be connected to the first display device 10_1 and the second display device 10_2 through a connector. The control circuit board 1600 may convert an image source input from the outside into digital video data DATA, and transmit the digital video data DATA to the first display device 10_1 and the second display device 10_2 through the connector.

In one or more embodiments, the control circuit board 1600 may be to transmit digital video data DATA corresponding to a left eye image improved or optimized for the user's left eye to the first display device 10_1 and transmit digital video data DATA corresponding to a right eye image improved or optimized for the user's right eye to the second display device 10_2. In one or more embodiments, the control circuit board 1600 may be to transmit the same digital video data DATA to the first display device 10_1 and the second display device 10_2.

The display device housing portion 1100 serves to house the first display device 10_1, the second display device 10_2, the middle frame 1400, the first optical member 1510, the second optical member 1520, and the control circuit board 1600. The housing portion cover 1200 is arranged to cover one open surface of the display device housing portion 1100. The housing portion cover 1200 may include the first eyepiece 1210 at which the user's left eye looks and the second eyepiece 1220 at which the user's right eye looks. It has been illustrated in FIG. 13 and FIG. 14 that the first eyepiece 1210 and the second eyepiece 1220 are separately arranged, but embodiments of the present disclosure are not limited thereto. In one or more embodiments, the first eyepiece 1210 and the second eyepiece 1220 may be merged as one piece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

The head mounted band 1300 serves to fix the display device housing portion 1100 to a user's head so that the first eyepiece 1210 and the second eyepiece 1220 of the housing portion cover 1200 may be maintained in a state where they are aligned with the user's left eye and right eye, respectively. In one or more embodiments, when the display device housing portion 1200 is implemented to have a light weight and a small size, the head mounted display device 1000 may include an eyeglass frame instead of the head mounted band 1300.

In one or more embodiments, the head mounted display device 1000 may further include a battery for supplying power, an external memory slot for housing an external memory, and an external connection port and a wireless communication module for receiving an image source. The external connection port may be at least one of a universe serial bus (USB) terminal, a display port, or a high-definition multimedia interface (HDMI) terminal, and the wireless communication module may be at least one of a 5G communication module, a 4G communication module, a wireless fidelity (WiFi) module, or a Bluetooth module.

The display device 1000 may have a same structure as the display device 10 described throughout FIGS. 1 to 11.

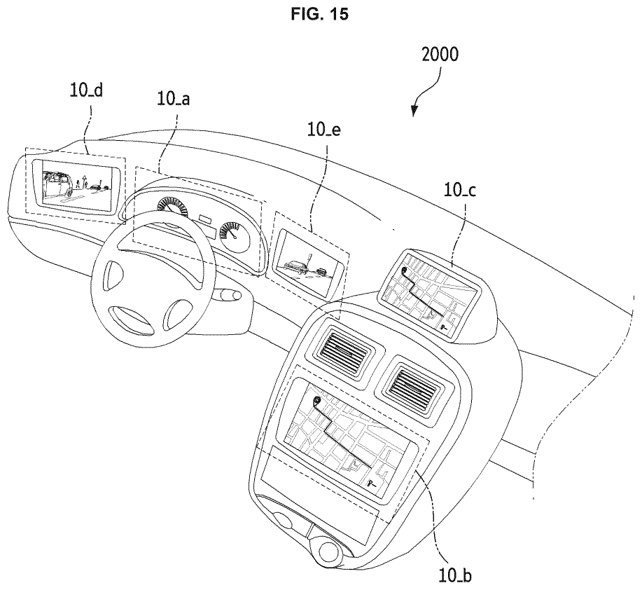

FIG. 15 is an illustrative view illustrating an instrument board and a center fascia of a vehicle including display devices 10_a, 10_b, 10_c, 10_d, and 10_e according to one or more embodiments of the present disclosure. For example, a vehicle to which display devices 10_a, 10_b, 10_c, 10_d, and 10_e according to one or more embodiments are applied is illustrated in FIG. 15.

Referring to FIG. 15, the display devices 10_a, 10_b, and 10_c according to one or more embodiments may be applied to an instrument board of the vehicle, applied to a center fascia of the vehicle, and/or applied to a center information display (CID) arranged on a dashboard of the vehicle. In one or more embodiments, the display devices 10_d and 10_e according to one or more embodiments may be applied to a room mirror display substituting for a side mirror of the vehicle.

Each of the display devices 10_a, 10_b, 10_c, 10_d, and 10_e may have a same structure as the display device 10 described throughout FIGS. 1 to 11.

The display device according to one or more embodiments may be applied to one or more suitable electronic devices. The electronic device according to one or more embodiments includes the display device described above and may further include modules or devices having additional functions in addition to the display device.

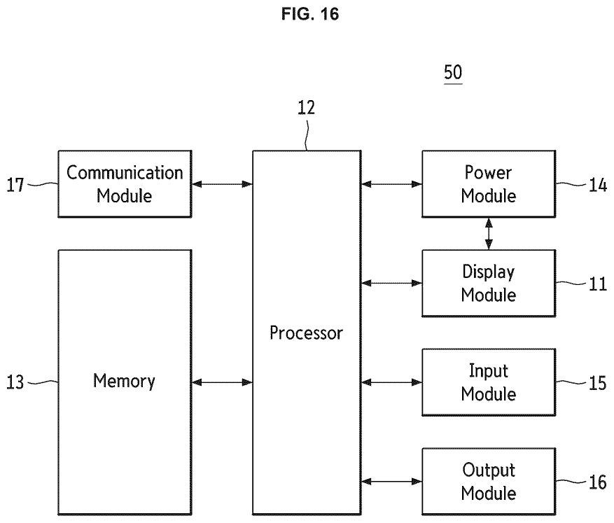

FIG. 16 is a block diagram of an electronic device according to one or more embodiments of the present disclosure. Referring to FIG. 16, an electronic device 50 according to one or more embodiments may include a display module 11, a processor 12, a memory 13, and a power module 14. The electronic device 5000 may further include an input module 15, a non-image output module 16, and/or a communication module 17.

The electronic device 50 may output one or more suitable information in the form of images through the display module 11. When the processor 12 executes an application stored in the memory 13, image information provided by the application may be provided to a user through the display module 11. The power module 14 may include a power supply module such as a power adapter and/or a battery device, and a power conversion module that converts the power supplied by the power supply module to generate power desired or required for an operation of the electronic device 50. The input module 15 may provide input information to the processor 12 and/or the display module 11. The non-image output module 16 may receive information other than images transmitted from the processor 12, such as sound, haptics, and light, and provide the information to the user. The communication module 17 is a module that is responsible for transmitting and receiving information between the electronic device 50 and an external device, and may include a receiving unit and a transmitting unit.

At least one selected from among the components of the electronic device 50 described above may be included in the display device according to one or more embodiments described above. In addition, some of the individual modules functionally included in one module may be included in the display device, and others may be provided separately from the display device. For example, the display device includes the display module 11, and the processor 12, the memory 13, and the power module 14 may be provided in the form of other devices within the electronic device 50 other than the display device.

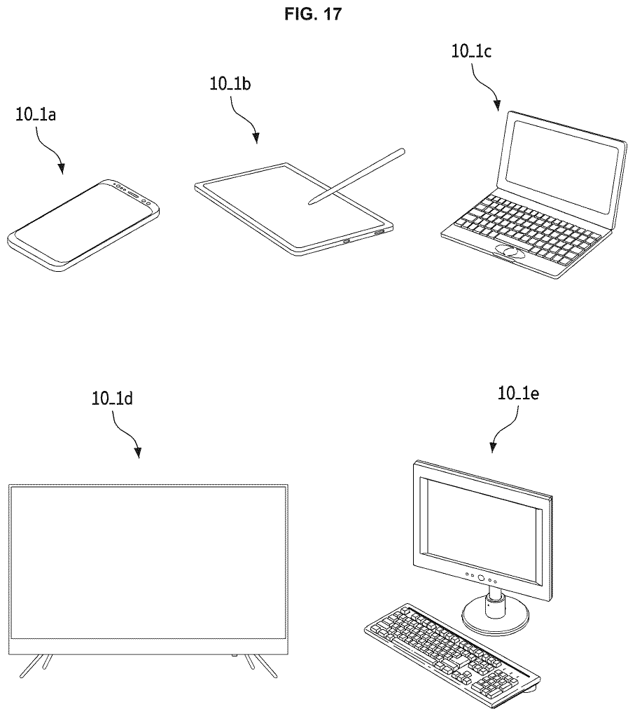

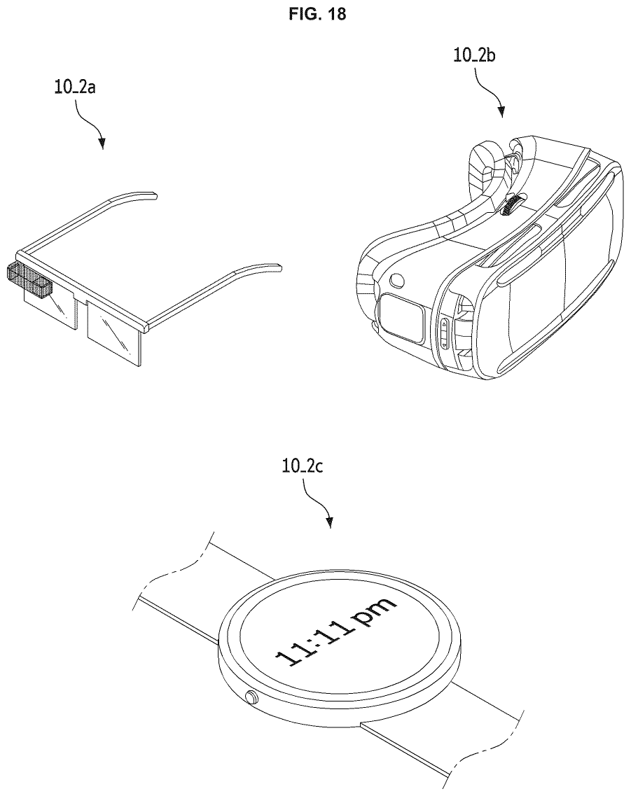

FIGS. 17 and 18 are schematic diagrams of electronic devices according to various suitable embodiments of the present disclosure.

FIG. 17 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

FIG. 18 shows an example of an electronic device including a display module being applied to a wearable electronic device. The wearable electronic device may be a smart glasses 10_2a, a head-mounted display 10_2b, a smart watch 10_2c, and/or the like.

The smart glasses 10_2a and the head-mounted display 10_2b may each include a display module that emits a display image and a reflector that reflects the emitted display screen and provides it to user's eyes, thereby providing a virtual reality or an augmented reality screen to the user.

The smart watch 10_2c may include a biometric sensor as an input device, and may provide biometric information recognized by the biometric sensor to a user through the display module.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value.

The light emitting element, the display module, the display device, the electronic device/apparatus, the device-manufacturing apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with one other, partially or entirely, and may be technically interlocked and operated in various suitable ways, and each embodiment may be implemented independently of one other or in conjunction with one other in any suitable manner unless otherwise stated or implied.

In concluding the detailed description, those skilled in the art will appreciate that many variations and modifications may be made to the example embodiments without substantially departing from the principles of the precent disclosure. Therefore, the disclosed embodiments of present disclosure are used in a generic and descriptive sense only and not for purposes of limitation. It is further understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device comprising:
a substrate;
a pixel transistor on the substrate;
an anode electrode on the pixel transistor and connected to the pixel transistor;
a light emitting layer on the anode electrode;
a pixel defining film on the light emitting layer;
a cathode electrode on the light emitting layer and the pixel defining film; and
a gate driver in a non-display area of the substrate and connected to the pixel transistor,
wherein the gate driver comprises a first transistor and a second transistor on the substrate, and
wherein a first gate electrode of the first transistor and a second gate electrode of the second transistor are directly connected to each other.

2. The display device of claim 1,
wherein the first transistor comprises:
a first source electrode;
a first drain electrode;
a first channel region in a first active layer on the substrate; and
the first gate electrode on the first active layer to overlap the first channel region of the first active layer.

3. The display device of claim 2,
wherein the second transistor comprises:
a second source electrode;
a second drain electrode;
a second channel region in a second active layer on the substrate; and
the second gate electrode on the second active layer to overlap the second channel region of the second active layer.

4. The display device of claim 3,
wherein the second gate electrode is directly connected to the first gate electrode through a contact hole penetrating an insulating layer.

5. The display device of claim 3,
wherein the second transistor further comprises a counter gate electrode on the substrate to overlap the second channel region of the second active layer, and
wherein the second active layer is between the counter gate electrode and the second gate electrode.

6. The display device of claim 5,
wherein the second gate electrode is directly connected to the counter gate electrode through a contact hole penetrating an insulating layer.

7. The display device of claim 2,
wherein the first active layer comprises a material comprising a low temperature polycrystalline silicon.

8. The display device of claim 3,
wherein the second active layer is an oxide-based active layer.

9. The display device of claim 8,
wherein the second active layer is composed of a material comprising indium-gallium-zinc-oxide or indium-gallium-zinc-tin oxide.

10. The display device of claim 1,
wherein the gate driver further comprises a capacitor directly connected to the second gate electrode of the second transistor.

11. The display device of claim 10,
wherein the capacitor comprises:
a first capacitor electrode on the substrate and directly connected to the second gate electrode; and
a second capacitor electrode on the first capacitor electrode to overlap the first capacitor electrode.

12. The display device of claim 11,
wherein the second gate electrode is directly connected to the first capacitor electrode through a contact hole penetrating an insulating layer.

13. The display device of claim 3,
wherein the first active layer and the second active layer are on different layers.

14. The display device of claim 1,
wherein the first transistor is a P-type transistor, and
the second transistor is an N-type transistor.

15. An electronic device comprising a display device with a screen,
wherein the display device comprises:
a substrate;
a pixel transistor on the substrate;
an anode electrode on the pixel transistor and connected to the pixel transistor;
a light emitting layer on the anode electrode;
a pixel defining film on the light emitting layer;
a cathode electrode on the light emitting layer and the pixel defining film; and
a gate driver in a non-display area of the substrate and connected to the pixel transistor,
wherein the gate driver comprises a first transistor and a second transistor on the substrate, and
wherein a first gate electrode of the first transistor and a second gate electrode of the second transistor are directly connected to each other.

16. The electronic device of claim 15,
wherein the first transistor comprises:
a first source electrode;
a first drain electrode;
a first channel region in a first active layer on the substrate; and
the first gate electrode on the first active layer to overlap the first channel region of the first active layer.

17. The electronic device of claim 16,
wherein the second transistor comprises:
a second source electrode;
a second drain electrode;
a second channel region in a second active layer on the substrate; and
the second gate electrode on the second active layer to overlap the second channel region of the second active layer.

18. The electronic device of claim 17,
wherein the second gate electrode is directly connected to the first gate electrode through a contact hole penetrating an insulating layer.

19. The electronic device of claim 17,
wherein the second transistor further comprises a counter gate electrode on the substrate to overlap the second channel region of the second active layer, and
the second active layer is between the counter gate electrode and the second gate electrode.

20. A vehicle comprising a display device,
wherein the display device comprises:
a substrate;
a pixel transistor on the substrate;
an anode electrode on the pixel transistor to be connected to the pixel transistor;
a light emitting layer on the anode electrode;
a pixel defining film on the light emitting layer;
a cathode electrode on the light emitting layer and the pixel defining film; and
a gate driver in a non-display area of the substrate and connected to the pixel transistor,
wherein the gate driver comprises a first transistor and a second transistor on the substrate, and
wherein a first gate electrode of the first transistor and a second gate electrode of the second transistor are directly connected to each other.
